(19) United States
(12) Patent Application Publication
(10) Pub. No.: US 2026/0010687 A1
(43) Pub. Date: Jan. 8, 2026

(54) SIMULATION APPARATUS, RECORDING MEDIUM, AND SIMULATION METHOD

(71) Applicant: ROHM CO., LTD., Kyoto-shi (JP)

(72) Inventors: Kenji HAMACHI, Kyoto-shi (JP); Koji TAMANO, Kyoto-shi (JP)

(21) Appl. No.: 19/257,651

(22) Filed: Jul. 2, 2025

(30) Foreign Application Priority Data
Jul. 3, 2024 (JP) 2024-107481

(51) Int. Cl. G06F 30/27

(52) U.S. Cl. CPC G06F 30/27

(57) ABSTRACT

A model setting unit executes setting related to a first chunk of input data and a second chunk of training data on a basis of loaded training-purpose data as well as setting related to a third chunk of test input data and a fourth chunk of expected data on a basis of loaded test-purpose data. A model computing unit executes computations of training with use of a machine learning model on a basis of the first chunk and the second chunk, further executes computations of prediction with use of the machine learning model on a basis of results of the training and the third chunk and arithmetically compares results of the prediction and the fourth chunk with each other. The machine learning model after execution of at least part of the computations of training is stored non temporarily.

### CROSS REFERENCE TO RELATED APPLICATIONS

The present invention claims priority under 35 U.S.C. § 119 to Japanese Patent Application No. 2024-107481 filed on Jul. 3, 2024, the entire contents of which are hereby incorporated by reference.

### BACKGROUND OF THE INVENTION

### 1. Technical Field

The present disclosure relates to a simulation apparatus, a recording medium, and a simulation method.

### 2. Description of Related Art

Conventionally, AI (Artificial Intelligence) is increasingly employed in condition-based maintenance of a mechanical system for the maintenance of factory equipment in industrial fields (e.g., WO 2019/035279).

### BRIEF DESCRIPTION OF THE DRAWINGS

FIG. 1 is a diagram showing the configuration of a computer according to an exemplary embodiment of the present disclosure.

FIG. 2 is a diagram showing the configuration of a simulation apparatus according to the exemplary embodiment of the disclosure.

FIG. 3 is a diagram for explanation of supervised training.

FIG. 4 is a diagram for explanation of future prediction as an example of a task of supervised training.

FIG. 5 is a view showing a first setting screen.

FIG. 6 is a view showing a dialog box.

FIG. 7 is a view showing one example of data in a training-purpose file.

FIG. 8 is a view showing a first setting screen.

FIG. 9 is a view showing a setting example of chunks of input data.

FIG. 10 is a view showing a setting example of chunks of training data.

FIG. 11 is a view showing a first setting screen.

FIG. 12 is a view showing a second setting screen.

FIG. 13 is a view showing a dialog box.

FIG. 14 is a view showing a data example of a test-purpose file.

FIG. 15 is a view showing a second setting screen.

FIG. 16 is a view showing a setting example of chunks in test input data.

FIG. 17 is a view showing a setting example of chunks in expected data.

FIG. 18 is a view showing a second setting screen.

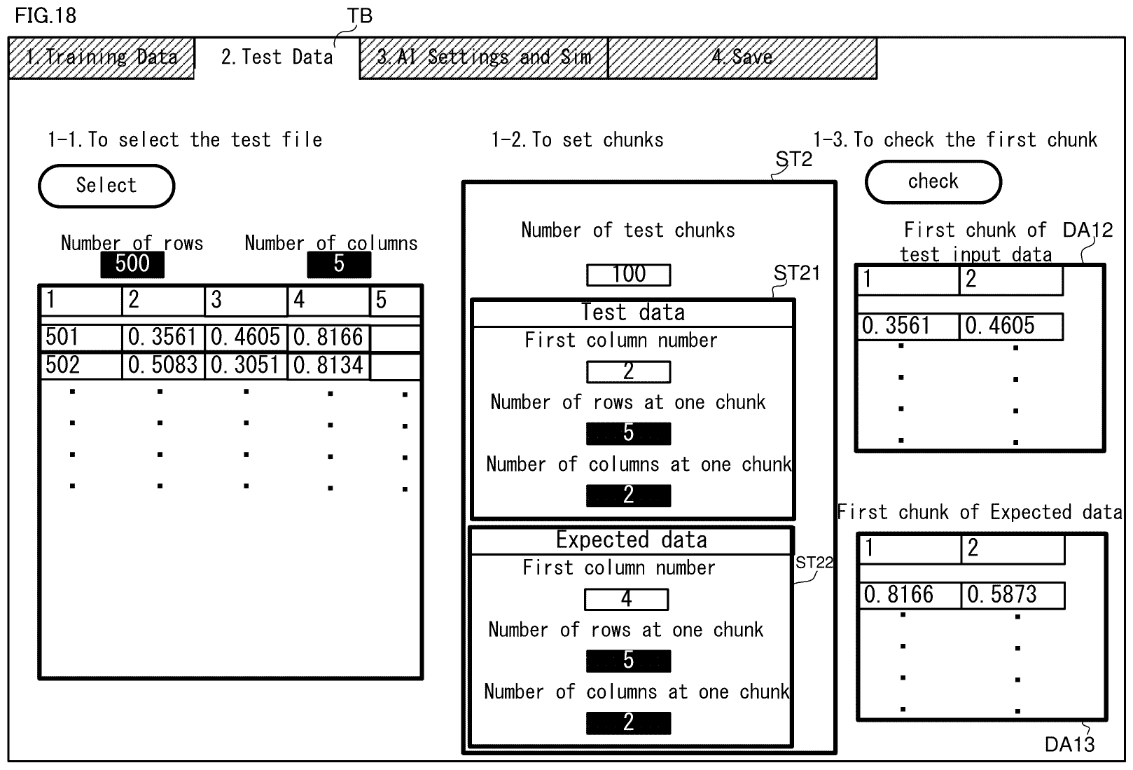

FIG. 19 is a view showing a third setting screen.

FIG. 20 is a diagram showing a three-layer neural network.

FIG. 21 is a view showing a state in which a tab TB2 has been changed over in the third setting screen.

FIG. 22 is a view showing a save screen.

FIG. 23 is a view showing one example in which β and P of a machine learning model after execution of computations of training (trained machine learning model) are displayed in a matrix form.

FIG. 24 is a view showing one example in which β of the machine learning model after execution of computations of training (trained machine learning model) is displayed in a matrix form.

FIG. 25 is a view showing one example in which P of the machine learning model after execution of computations of training (trained machine learning model) is displayed in a matrix form.

FIG. 26 is a view showing a third setting screen according to a modification.

FIG. 27 is a view showing one example of training-purpose data for a full charging capacity simulation.

FIG. 28 is a graph showing one example of future prediction of a full charging capacity simulation.

### DETAILED DESCRIPTION OF PREFERRED EMBODIMENTS

Now, an exemplary embodiment of the present disclosure will be described with reference to accompanying drawings.

### <Configuration of Computer>

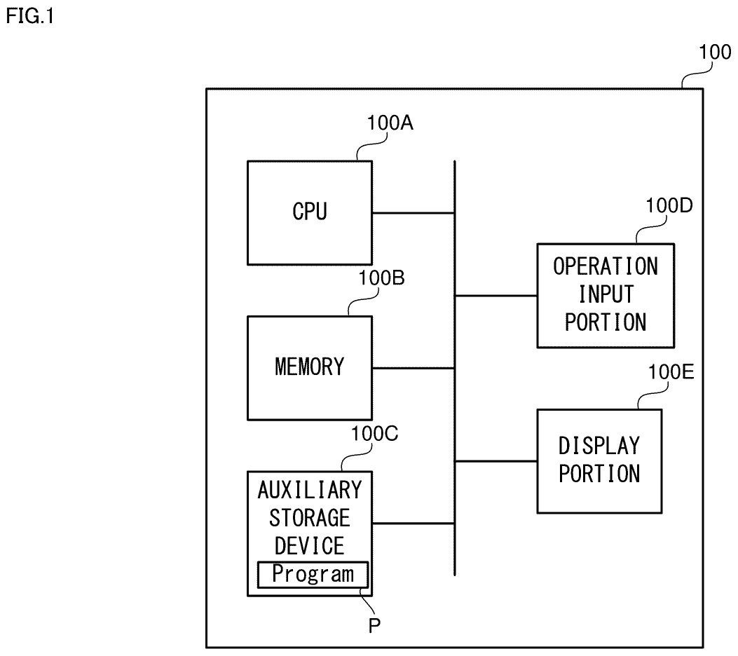

FIG. 1 is a diagram showing the configuration of a computer 100 according to an exemplary embodiment of the present disclosure. The computer 100 functions as a later-described simulation apparatus according to the present disclosure. The computer 100 is, for example, a PC (personal computer). Given a PC as the computer 100, it is no matter whether the PC is desktop type or notebook type.

The computer 100 includes a CPU (central processing unit) 100A, a memory 100B, an auxiliary storage device 100C, an operation input portion 100D, and a display portion 100E.

The CPU 100A includes a control device and a computation device (neither is shown). The control device interprets instructions in a program to control the different parts of the computer 100. The computation device executes arithmetic operations.

The memory 100B is a semiconductor storage device that temporarily stores a program or data. The information stored in the memory 100B is lost when the power to the computer 100 is turned off.

The auxiliary storage device 100C is configured with an HDD (hard disk drive), an SSD (solid-state drive), or the like and stores a program or data. The program stored in the auxiliary storage device 100C is read into the memory 100B. The CPU 100A executes the program read into the memory 100B.

The operation input portion 100D is configured with a keyboard, a mouse, and the like and feeds the computer 100 with the input of user operations. The information input through the operation input portion 100D is fed to the memory 100B.

The display portion 100E is configured with, for example, a liquid crystal display and outputs the information acquired from the memory 100B in a form converted into an image.

### <Configuration of Simulation Apparatus>

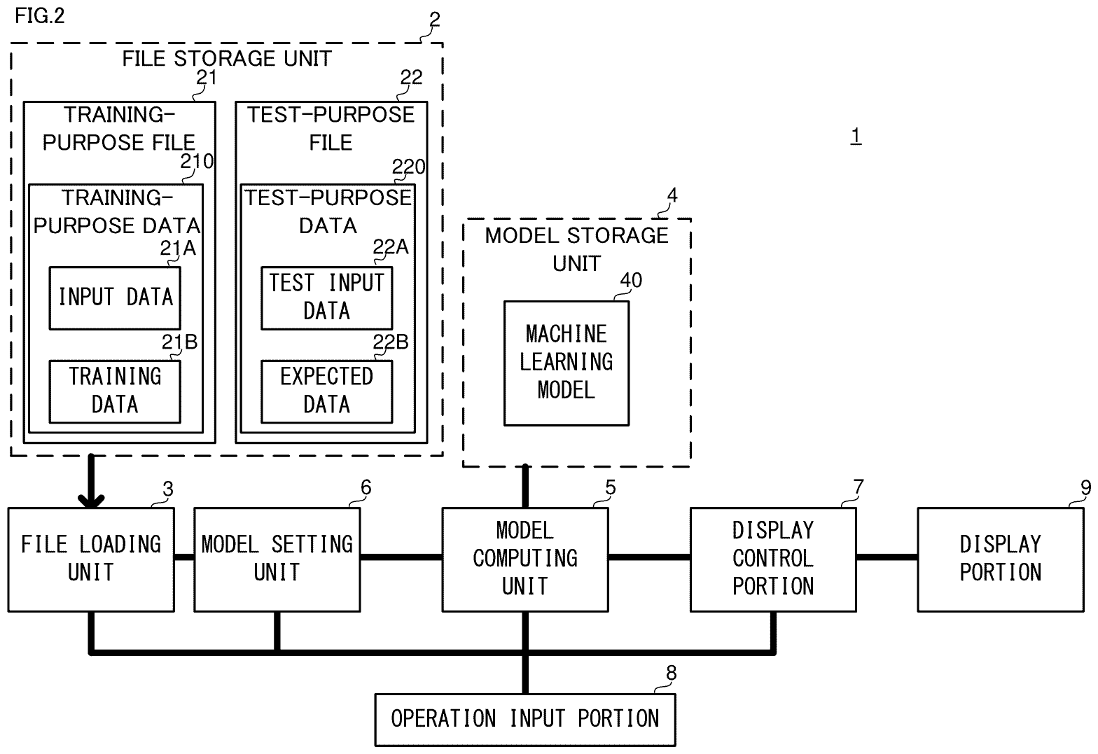

FIG. 2 is a diagram showing the configuration of a simulation apparatus 1 according to the exemplary embodiment of the disclosure. The simulation apparatus 1 is an apparatus capable of simulating training and prediction by machine training (AI).

The simulation apparatus 1 includes a file storage unit 2, a file loading unit 3, a model storage unit 4, a model computing unit 5, a model setting unit 6, a display control portion 7, an operation input portion 8, and a display portion 9.

The file storage unit 2, which stores a training-purpose file 21 and a test-purpose file 22, is configured with an auxiliary storage device 100C of the computer 100. The training-purpose file 21 and the test file 22 are configured each as an Excel (trademark) file as an example. In addition, the files may be stored into the auxiliary storage device 100C from outside of the computer 100 via USB interface of the computer 100 or network interface (neither is shown in FIG. 1), as an example.

The training-purpose file 21 includes training-purpose data 210. The training-purpose data 210 includes input data 21A and training data 21B. The training-purpose data 210 is data for execution of so-called supervised training by feeding the input data 21A and the training data 21B as input and output, respectively, to a machine learning model 40 (described later).

The test-purpose file 22 includes test-purpose data 220. The test-purpose data 220 includes test input data 22A and expected data 22B. Entering the test input data 22A into the machine learning model 40, followed by execution of prediction, causes prediction data to be outputted from the machine learning model 40. The outputted prediction data is compared with the expected data (later-described creation of anomaly scores or the like).

The file loading unit 3 loads the training-purpose 21 and the test-purpose file 22 from the file storage unit 2.

The model storage unit 4, which has stored a machine learning model 40, is configured with the auxiliary storage device 100C of the computer 100. The machine learning model 40 is configured as part of a program P by, for example, MATLAB/Simulink (trademark). Concrete examples of the machine learning model 40 will be described later.

Individual functions of the file loading unit 3, the model computing unit 5, the model setting unit 6, and the display control portion 7 are implemented by the program P executed by the CPU 100A. In addition, the operation input portion 8 and the display portion 9 are equivalent to the operation input portion 100D and the display portion 100E, respectively, of the computer 100.

The model computing unit 5 executes a simulation by executing computing process of the machine learning model 40 stored in the model storage unit 4. The model setting unit 6, in response to inputs from the operation input portion 8, executes settings (setting of data to be used for training and prediction, setting of parameters, setting of types of functions, etc.) related to the machine learning model 40 stored in the model storage unit 4. Simulations by the model computing unit 5 are executed according to setting contents by the model setting unit 6. The display control portion 7 executes control process that allows various types of screens such as later-described setting screens to be displayed on the display portion 9 in response to inputs from the operation input portion 8.

For example, applications of machine learning are increasingly employed in condition-based maintenance of mechanical systems for the maintenance of factory equipment in industrial fields. However, even when a user tries to execute an expected AI algorithm, there is a necessity for providing data to an AI vendor or other AI developer. Since the data, in many cases, includes secret information associated with a product and its manufacturing process, it is hard to disclose the data. Therefore, it has conventionally been the only way for such a case that various cases of the AI vendor or the like are referenced, or that an open problem which has become a common benchmark for AI performance (e.g., housing price prediction in Boston, physical property estimation of diesel fuel, etc.) is given as a problem to be solved, followed by a judgment whether it is suitable as a user's problem and for problem solution. As a matter of course, such an open problem is inconsistent with a user's problem and issue. For this reason, when a selected AI algorithm is applied to user's data, there would often be the case where it proves clear a posteriori that the selected AI algorithm had been inappropriate or less appropriate. As a result of this, reselection of an AI algorithm would cause a disadvantage for both the user and the AI vendor.

As described above, event in a user's attempt to know what kind of achievements can be fulfilled by using user's acquired data, there is a need for sharing the data with outside (AI vendor or IC maker having AI solution etc.). That is, there is a risk of getting out the data, which is secret information. Also, it is a difficulty whether data, when provided alone, can be properly analyzed by outside or not; it is difficult to attain proper adjustment of AI parameters without high-level knowledge as to a domain of which data has been acquired by the user. Transmission of domain knowledge from the user to the AI vendor or the like also involves quite large time and effort, while gaps in background knowledge cause communication errors to be more likely to occur. Further, data acquired by the user cannot be analyzed on a same-day and in-place basis.

Under the above-described circumstances, using the simulation apparatus 1 according to the present disclosure makes it possible to effectively verify AI effect of supervised training with a user's own data. As a result of this, for example, there can be fulfilled such effects as elimination of a risk of getting out secret-information data, and practicalization of in-place analysis of acquired data. In particular, the present disclosure, as will be described later, has introduced a concept of chunk for setting of input data and output data into a machine learning model, facilitating such settings as entering plural types of input data on a plural-data-piece basis.

### <Supervised Training>

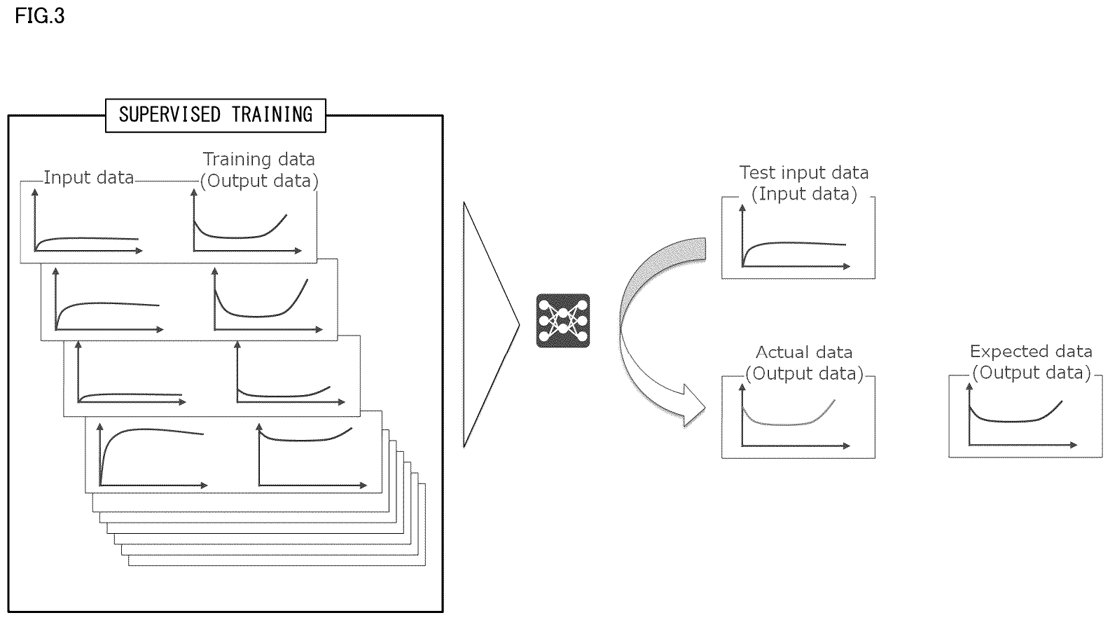

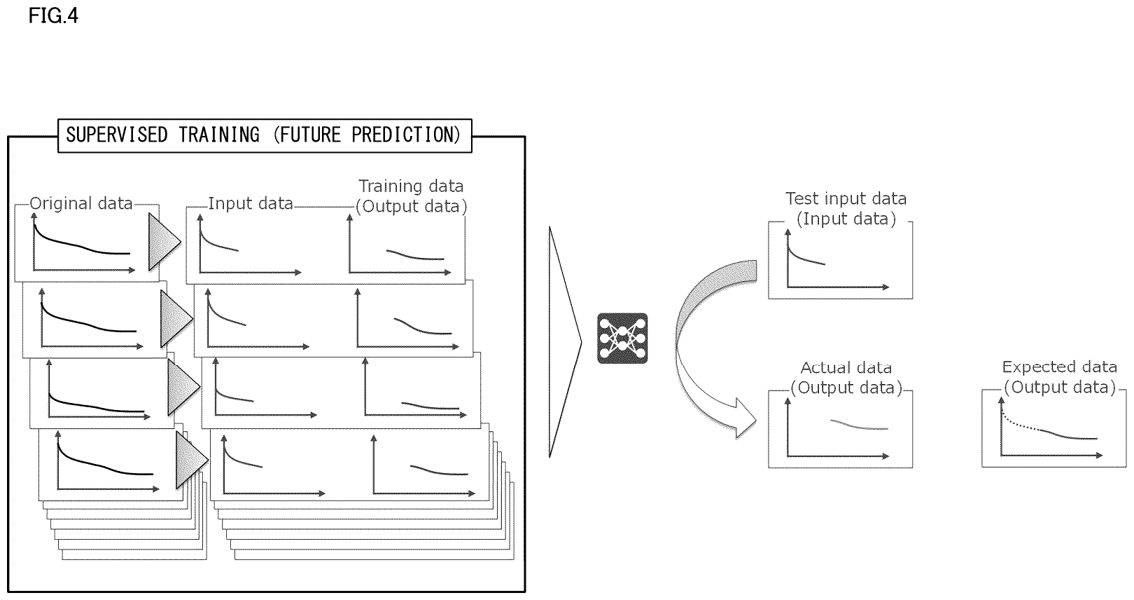

Now, supervised training will be described in summary. FIG. 3 is a diagram for explanation of supervised training. In the supervised training, input data as input and training data as output are given to a machine learning model (AI), and parameters of the machine learning model are trained. Thereafter, test input data is inputted to the machine learning model, and prediction data is outputted as a result of prediction exerted by the machine learning model. The outputted prediction data is compared with expected data. It is noted that in FIG. 3 and FIG. 4, prediction data is depicted as actual data, which is referred to as an object of comparison with the expected data.

FIG. 4 is a diagram for explanation of future prediction as an example of a task of supervised training. In this case, original data is divided into first-half input data and second-half training data on time series. Then, training by the machine learning model is executed with use of the input data and the training data. Thereafter, entering the first-half test input data on time series into the machine learning model causes the second-half actual data (prediction data) on time series to be outputted from the machine learning model. In this way, second-half data can be predicted based on first-half data on time series. Outputted actual data is compared with the expected data.

### <GUI>

Next, an explanation is given on a GUI (Graphical User Interface) that enables setting related to simulations in the simulation apparatus 1 according to this embodiment. Examples of various setting screens described below are displayed on the display portion 9 by the display control portion 7 (FIG. 2). Selections and settings in various setting screens, switching of screens, and the like are performed based on inputs by the operation input portion 8. Contents that are set in various setting screens are set by the model setting unit 6.

### <<Loading of Training-Purpose File>>

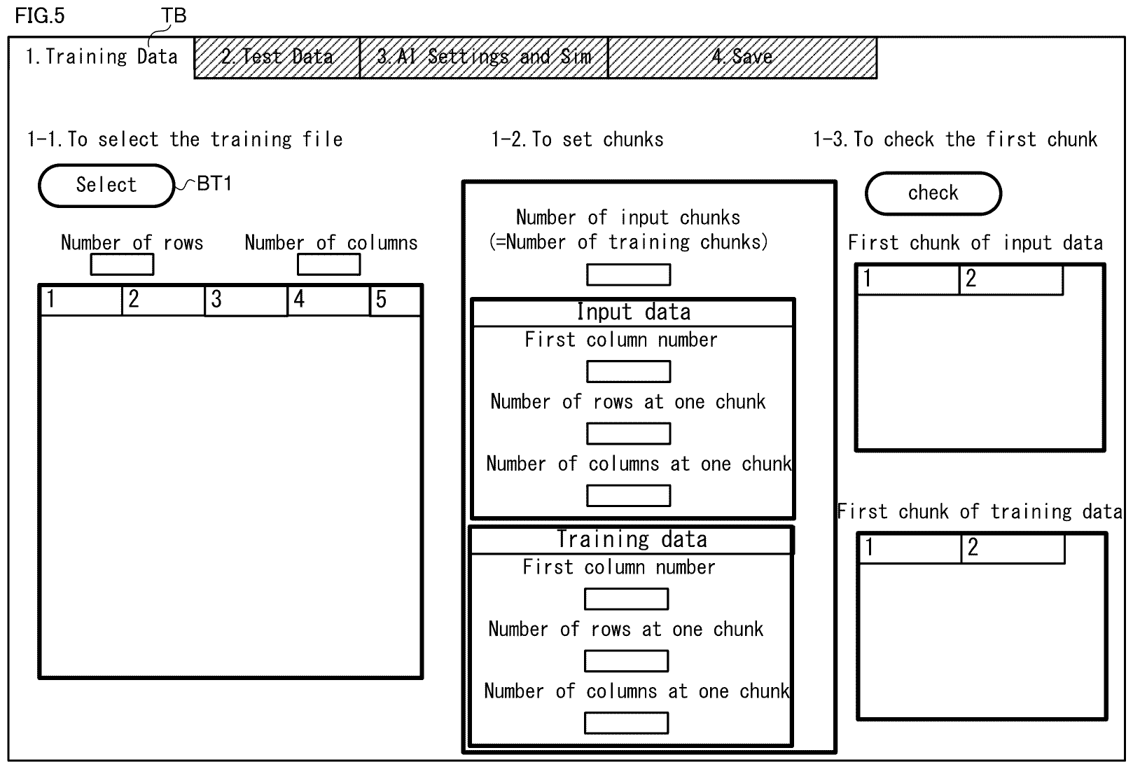

As the program P is started up, a first setting screen shown in FIG. 5 is displayed. The first setting screen is a screen for setting training-purpose data. In upper portion of the first setting screen, tabs TB are displayed in left-to-right array. Pressing the tabs allows the setting screen to be changed over. FIG. 5 shows a state in which a tab TB of “1. Training data” has been pressed.

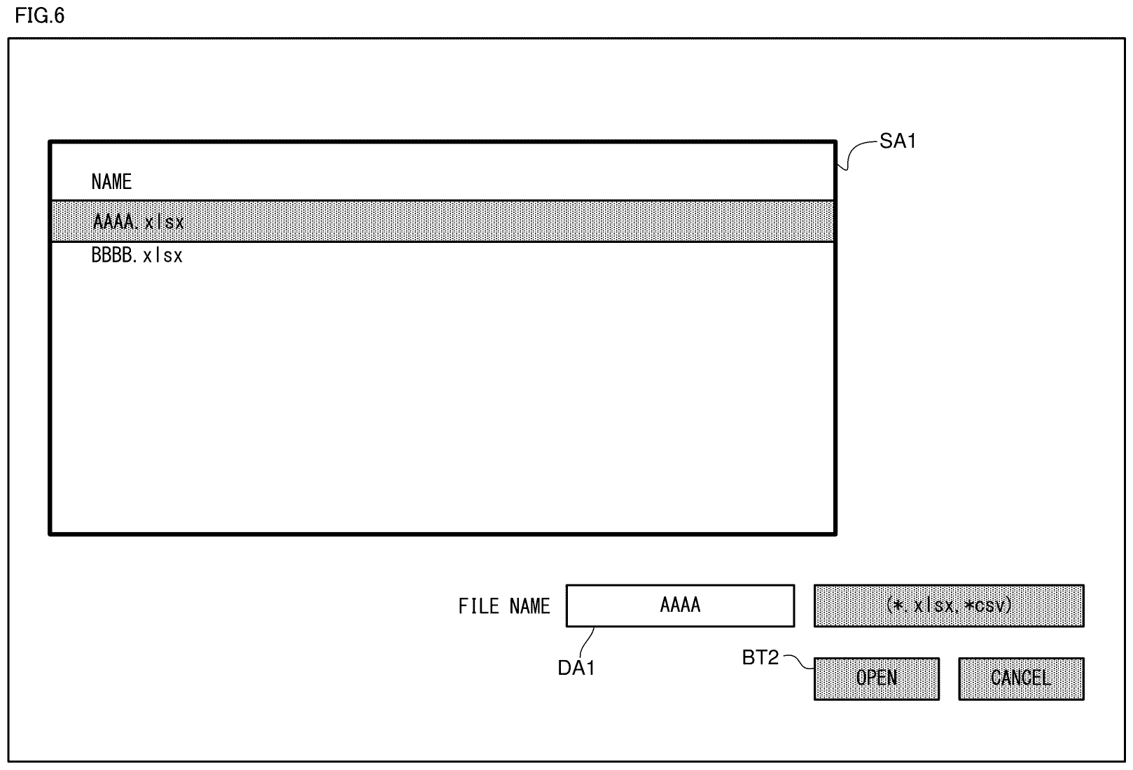

In the first setting screen, a select button BT1 for selection of a training-purpose file is displayed. Pressing the select button BT1 causes a dialog box shown in FIG. 6 to be displayed. In the dialog box, a list of file names is displayed in a selection area SA1. A file name selected in the selection area SA1 is displayed in a file-name display area DA1 given downward. When a decision button BT2 is pressed in the dialog box, a data file having the file name displayed in the file-name display area DA1 is loaded by the file loading unit 3. In this case, Excel files having an extension of xlsx are selectable.

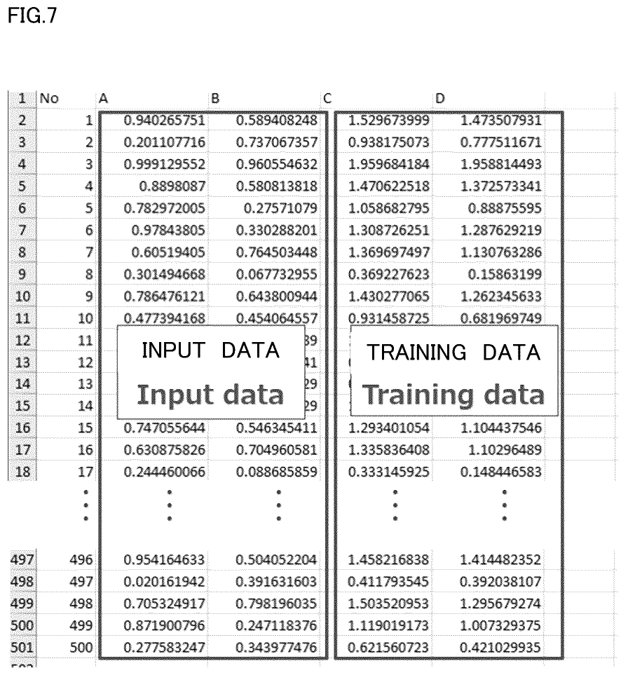

In this connection, FIG. 7 is a view showing one example of data in the training-purpose file. Depicted is an example of data values written in cells of the training-purpose file, which is an Excel file. The first column shows data No., the second column (Column A) shows random numbers in real number within a range of not less than 0 and less than 1, the third column (Column B) shows random numbers in real number within a range of not less than 0 and less than 1, the fourth column (Column C) shows each sum of values of Column A and Column B on each identical row, and the fifth column (Column D) shows each sum of squares of individual values of Column A and Column B on each identical row. Data of Column A and Column B become input data, and data of Column C and Column D become training data. A number of rows of 500, as an example, is set for each of input data and training data. In the following description, it is assumed that such a training-purpose file will be loaded.

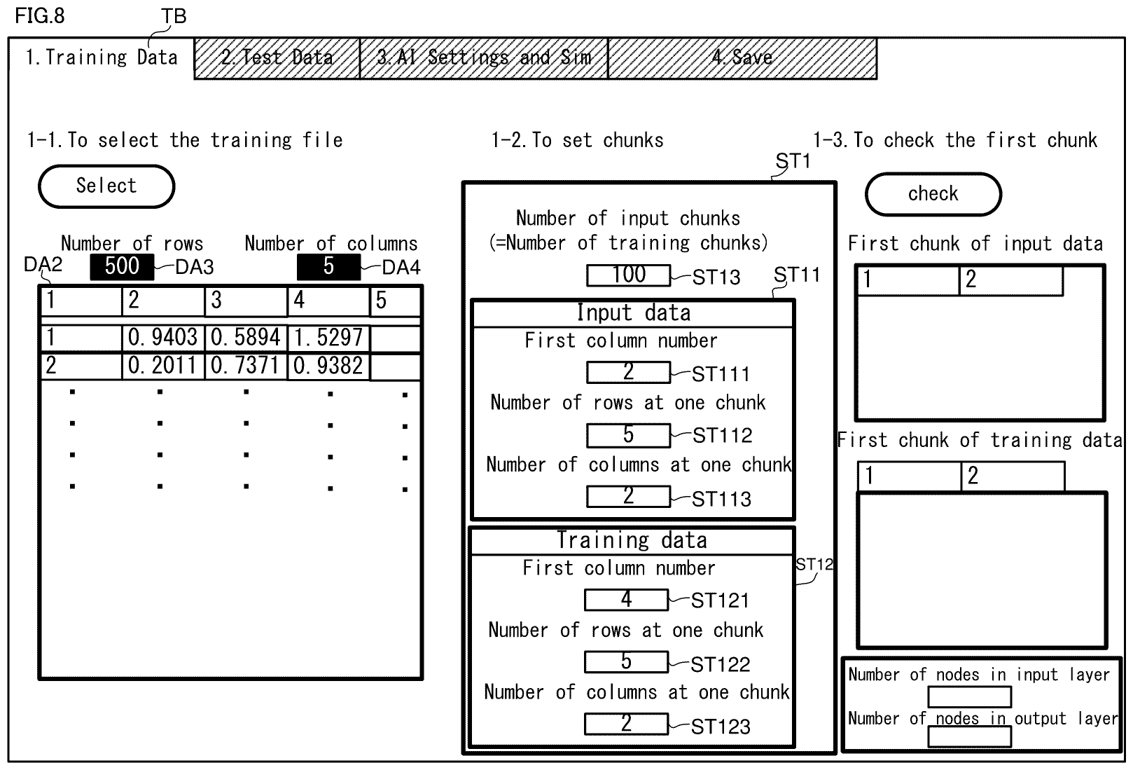

When a training-purpose file is loaded, data included in the loaded training-purpose file are displayed in a table form in a training-purpose data display area DA2 in the first setting screen as shown in FIG. 8. In addition, on condition that a variable name has been entered in the first row of the training-purpose file as shown in FIG. 7, data are loaded with the first row disregard. As a result, the user is allowed to verify that data have been loaded properly. Also, a number of rows of loaded data is displayed in a number-of-rows display area DA3, while a number of columns of loaded data is displayed in a number-of-columns display area DA4.

At a center of the first setting screen (FIG. 8), a chunk setting portion ST1 is displayed. The term ‘chunk’ refers to a batch block of data in sequential feed of data to the machine learning model 40. The chunk setting portion ST1 includes an input data setting portion ST11 and a training data setting portion ST12.

The input data setting portion ST11 includes a column-number setting portion ST111, a number-of-rows setting portion ST112, and a number-of-columns setting portion ST113. Enterable in the column-number setting portion ST111 is a column number in loaded data indicating a first column of input data. Enterable in the number-of-rows setting portion ST112 is a number of rows of one chunk in input data of loaded data. Enterable in the number-of-columns setting portion ST113 is a number of columns of one chunk in input data of loaded data.

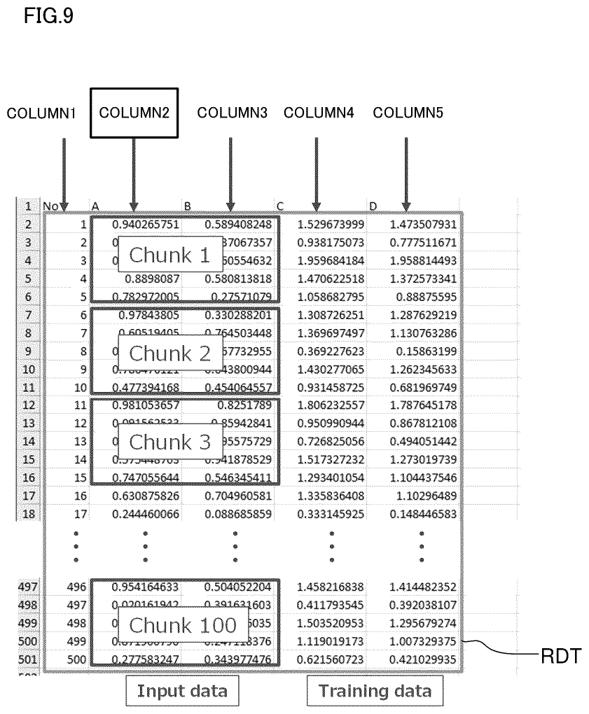

In the example of FIG. 8, ‘2’ has been entered in the column-number setting portion ST111, ‘5’ has been entered in the number-of-rows setting portion ST112, and ‘2’ has been entered in the number-of-columns setting portion ST113. As a result of this, as shown in FIG. 9, the second column of loaded data RDT is set as a first column of input data, and a data block of 5 rows by 2 columns is set as one chunk.

The training data setting portion ST12 includes a column-number setting portion ST121, a number-of-rows setting portion ST122, and a number-of-columns setting portion ST123. Enterable in the column-number setting portion ST121 is a column number of loaded data indicating a first column of training data. Enterable in the number-of-rows setting portion ST122 is a number of rows of one chunk in training data of loaded data. Enterable in the number-of-columns setting portion ST123 is a number of columns of one chunk in training data of loaded data.

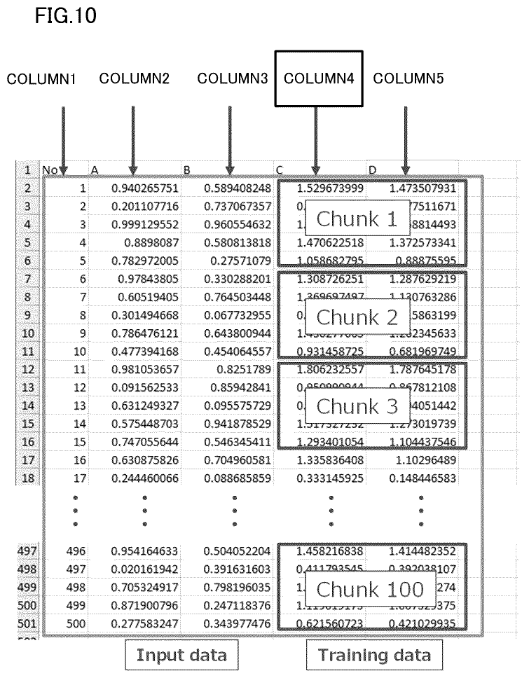

In the example of FIG. 10, ‘4’ has been entered in the column-number setting portion ST121, ‘5’ has been entered in the number-of-rows setting portion ST122, and ‘2’ has been entered in the number-of-columns setting portion ST123. As a result of this, as shown in FIG. 10, the fourth column of loaded data RDT is set as a first column of training data, and a data block of 5 rows by 2 columns is set as one chunk.

The chunk setting portion ST1 includes a number-of-chunks setting portion ST13. Enterable in the number-of-chunks setting portion ST13 is a number of chunks of each of input data and training data. The number of chunks needs to be equal to each other between input data and training data. In the example of FIG. 8, the number of chunks is set to ‘100’. As a result of this, chunks counting 100 are set as shown in FIG. 9 and FIG. 10. In addition, although values of the number-of-rows setting portion ST112 and the number-of-rows setting portion ST122 are equal to each other in FIG. 8, yet those may be set to values different from each other. Also, although values of the number-of-columns setting portion ST113 and the number-of-columns setting portion ST123 are equal to each other in FIG. 8, yet those may be set to values different from each other.

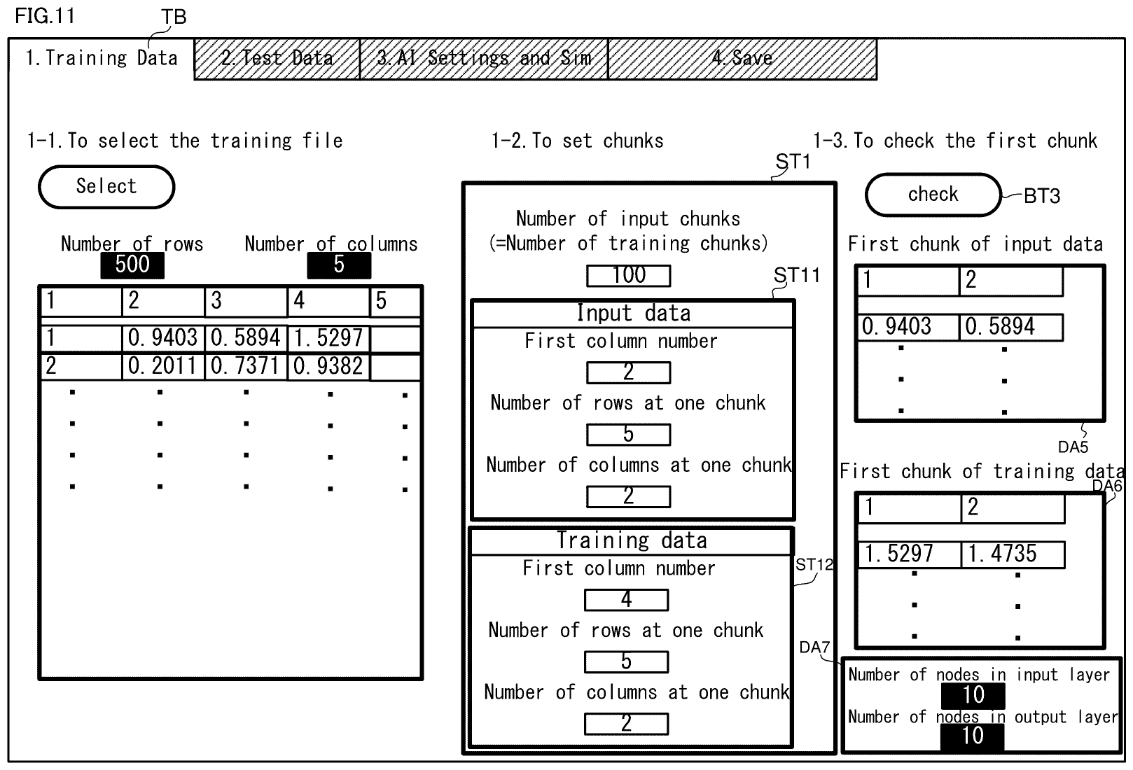

When a check button BT3 is pressed under a condition that a value has been entered into the chunk setting portion ST1, a screen display as shown in FIG. 11 results. In this case, a first chunk of input data which is set in response to setting contents of the input data setting portion ST11 is displayed in a chunk display area DA5. Also, a first chunk of training data which is set in response to setting contents of the training data setting portion ST12 is displayed in a chunk display area DA6. Also, a number of input nodes and a number of output nodes of the machine learning model 40 are displayed in a number-of-nodes display area DA7. The number of input nodes is a number of data pieces included in one chunk of input data. The number of output nodes is a number of data pieces included in one chunk of training data. Thus, in the example of FIG. 11, ‘10’ is displayed as both the number of input nodes and the number of output nodes.

### <<Loading of Test-Purpose File>>

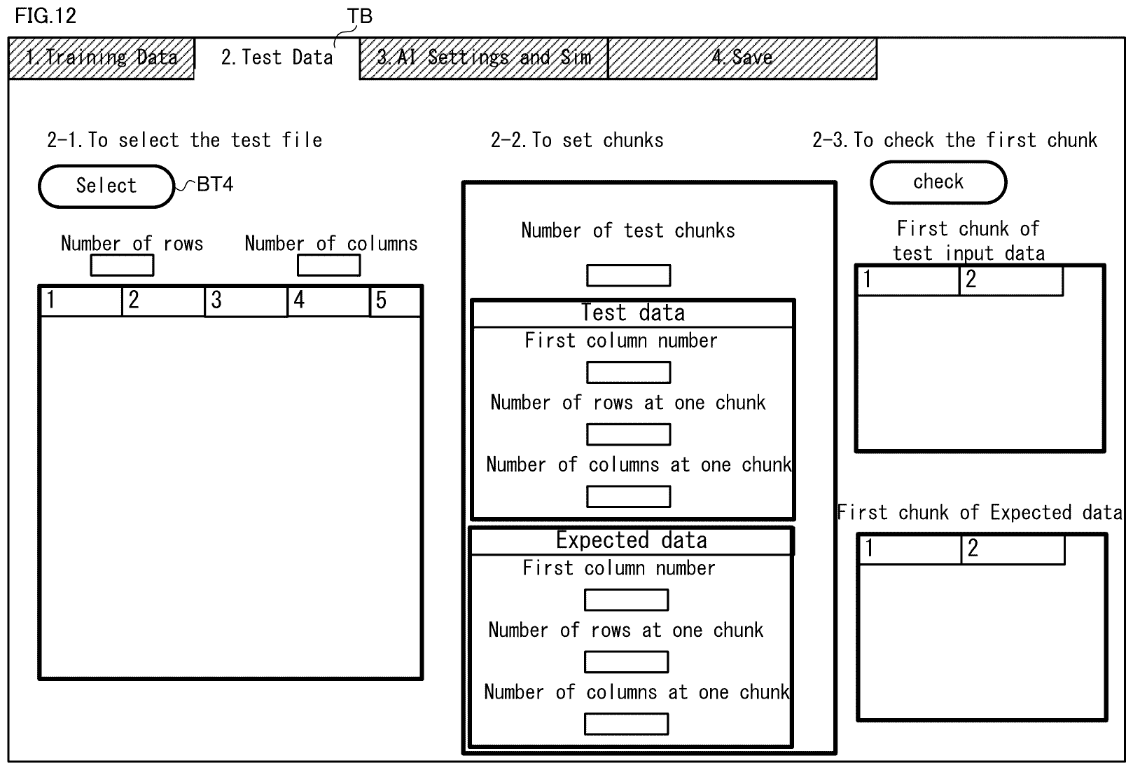

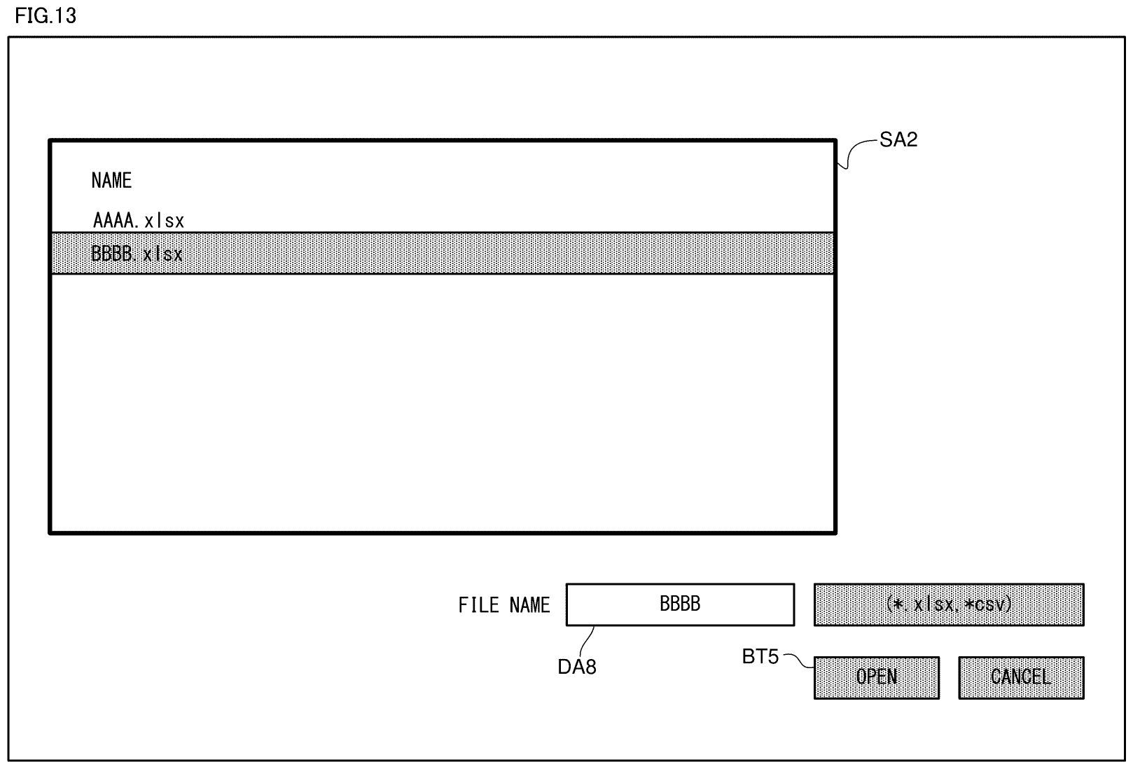

When a tab TB of “2. Test data” is pressed in the first setting screen, a second setting screen as shown in FIG. 12 is displayed. In the second setting screen, a select button BT4 for selection of a test-purpose file is displayed. Pressing the select button BT4 causes a dialog box shown in FIG. 13 to be displayed. In the dialog box, a list of file names is displayed in a selection area SA2. A file name selected in the selection area SA2 is displayed in a file-name display area DA8 given downward. When a decision button BT5 is pressed in the dialog box, a file having the file name displayed in the file-name display area DA8 is loaded by the file loading unit 3. In this case, Excel files having an extension of xlsx are selectable.

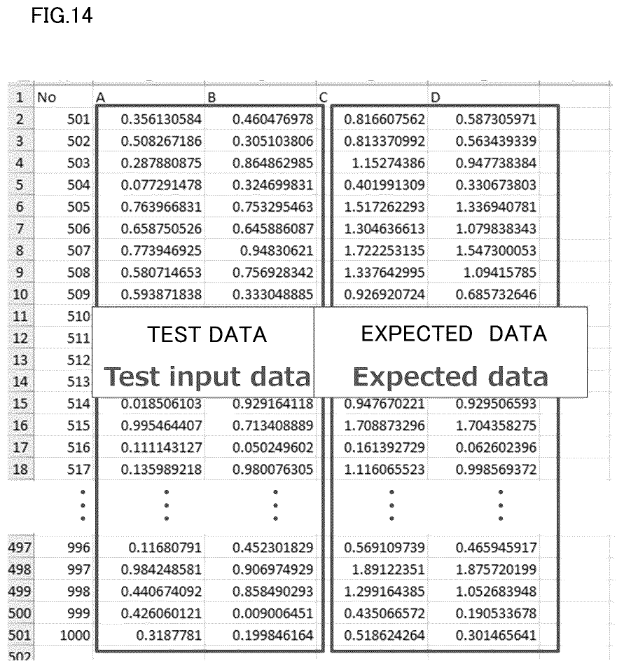

In this connection, FIG. 14 is a view showing a data example of a test-purpose filc. Depicted is an example of data values written in cells of a test-purpose file which is an Excel file. The first column shows data No., the second column (Column A) shows random numbers in real number within a range of not less than 0 and less than 1, the third column (Column B) shows random numbers in real number within a range of not less than 0 and less than 1, the fourth column (Column C) shows each sum of values of Column A and Column B on each identical row, and the fifth column (Column D) shows each sum of squares of individual values of Column A and Column B on each identical row. Data of Column A and Column B become test input data, and data of Column C and Column D become expected data. A number of rows of 500, as an example, is set for each of test input data and expected data. In the following description, it is assumed that such a test-purpose file will be loaded.

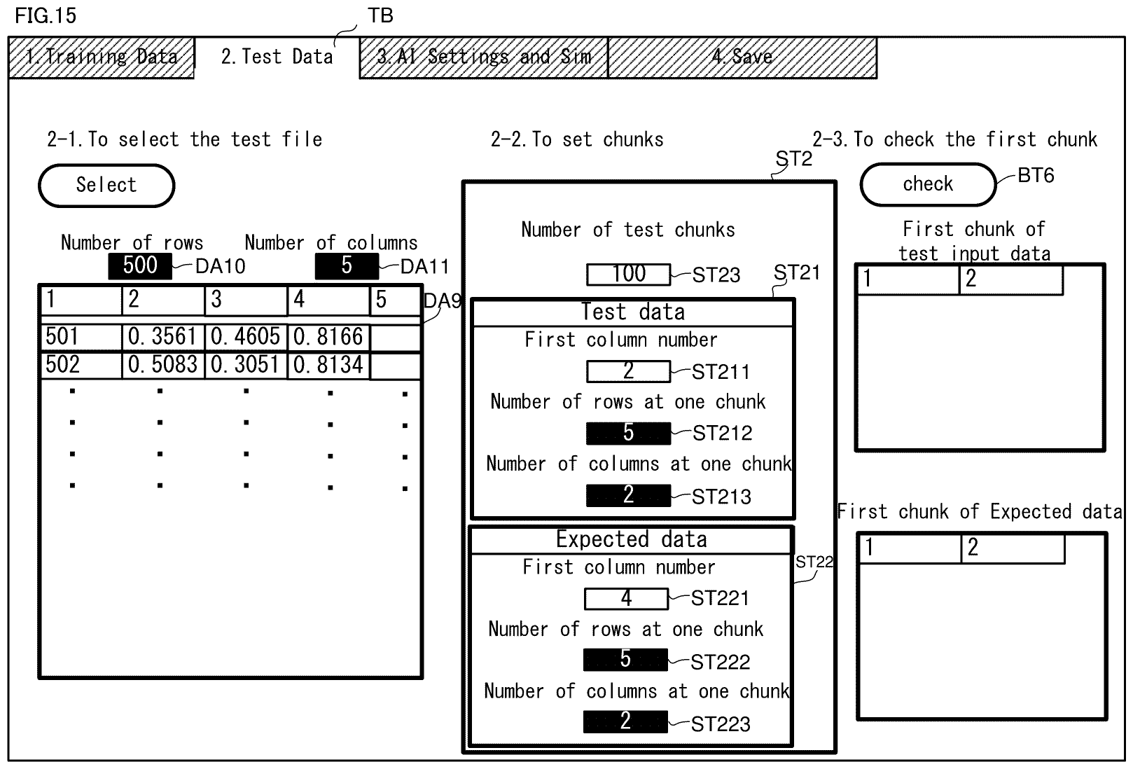

When a test-purpose file is loaded, data included in the loaded test-purpose file are displayed in a table form in a test-purpose data display area DA9 in the second setting screen as shown in FIG. 15. In addition, on condition that a variable name has been entered in the first row of the test-purpose file as shown in FIG. 14, data are loaded with the first row disregard. As a result, the user is allowed to verify that data have been loaded properly. Also, a number of rows of loaded data is displayed in a number-of-rows display area DA10, while a number of columns of loaded data is displayed in a number-of-columns display area DA11.

At a center of the second setting screen (FIG. 15), a chunk setting portion ST2 is displayed. The chunk setting portion ST2 includes a test-input-data setting portion ST21 and an expected data setting portion ST22.

The test-input-data setting portion ST21 includes a column-number setting portion ST211, a number-of-rows setting portion ST212, and a number-of-columns setting portion ST213. Enterable in the column-number setting portion ST211 is a column number in loaded data indicating a first column of test input data. Enterable in the number-of-rows setting portion ST212 is a number of rows of one chunk in test input data of loaded data. This number of rows is equal to a set number (entered into the number-of-rows setting portion ST112) of rows of one chunk in input data. In the number-of-columns setting portion ST213, a number of columns of one chunk in test input data of loaded data is displayed. The number of columns is equal to a set number of columns (entered into the number-of-columns setting portion ST113) of one chunk in input data.

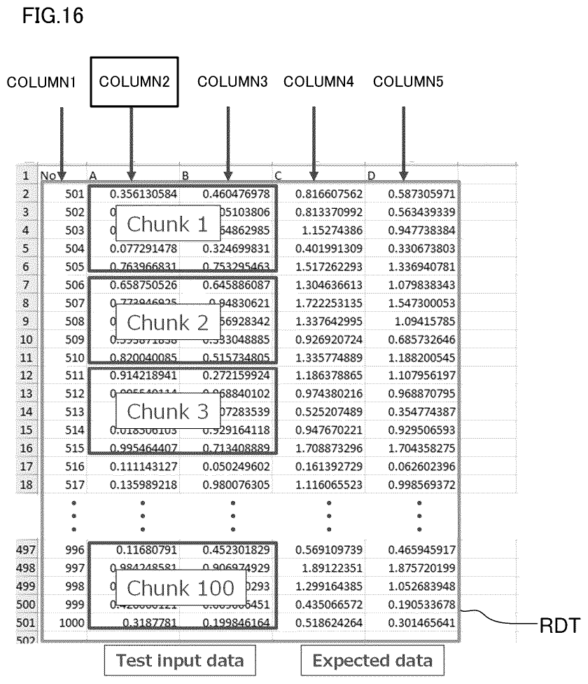

In the example of FIG. 15, ‘2’ has been entered in the column-number setting portion ST211, ‘5’ has been entered in the number-of-rows setting portion ST212, and ‘2’ has been entered in the number-of-columns setting portion ST213. As a result of this, as shown in FIG. 16, the second column of loaded data RDT is set as a first column of test input data, and a data block of 5 rows by 2 columns is set as one chunk.

The expected data setting portion ST22 includes a column-number setting portion ST221, a number-of-rows setting portion ST222, and a number-of-columns setting portion ST223. Enterable in the column-number setting portion ST221 is a column number in loaded data indicating a first column of expected data. Enterable in the number-of-rows setting portion ST222 is a number of rows of one chunk in expected data of loaded data. In the number-of-columns setting portion ST223, a number of columns of one chunk in expected data of loaded data is displayed.

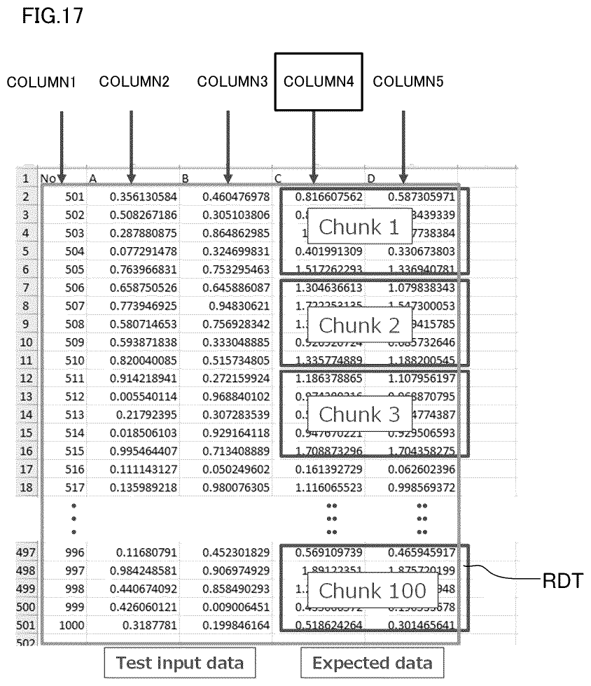

In the example of FIG. 15, ‘4’ has been entered in the column-number setting portion ST221, ‘5’ is displayed in the number-of-rows setting portion ST222, and ‘2’ is displayed in the number-of-columns setting portion ST223. As a result of this, as shown in FIG. 17, the fourth column of loaded data RDT is set as a first column of training data, and a data block of 5 rows by 2 columns is set as one chunk.

The chunk setting portion ST2 includes a number-of-chunks setting portion ST23. Enterable in the number-of-chunks setting portion ST23 are numbers of chunks of test input data and expected data, respectively. The number of chunks needs to be equal to each other between test input data and expected data. In the example of FIG. 15, the number of chunks is set as ‘100’. As a result of this, chunks counting ‘100’ are set as shown in FIG. 16 and FIG. 17.

When a check button BT6 is pressed under a condition that a value has been entered into the chunk setting portion ST2, a screen display as shown in FIG. 11 results. In this case, a first chunk of test input data which is set in response to setting contents of the test input data setting portion ST21 is displayed in a chunk display area DA12. Also, a first chunk of training data which is set in response to setting contents of the expected data setting portion ST22 is displayed in a chunk display area DA13.

### <<Setting of Machine Learning Model and Simulation>>

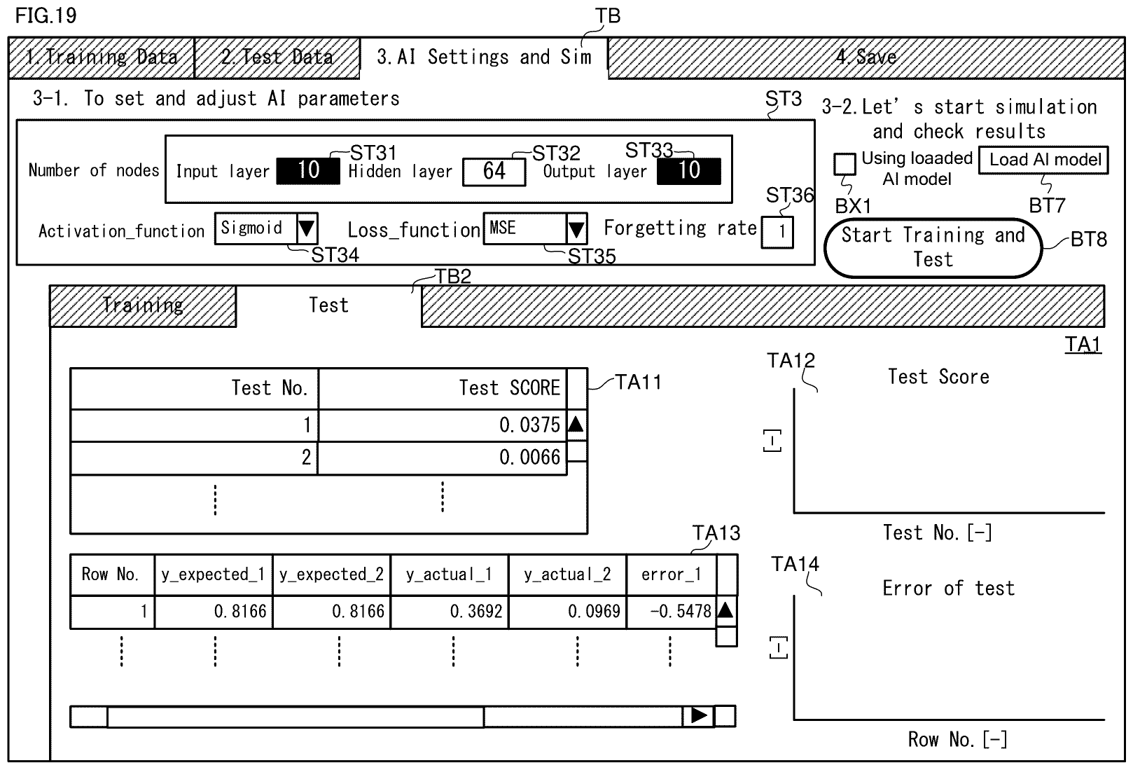

When a tab TB of “3. AI Settings and Sim” is pressed in the second setting screen, a third setting screen as shown in FIG. 19 is displayed. The third setting screen is a screen for parameter settings, simulation execution, and verification of simulation results for the machine learning model (AI) 40.

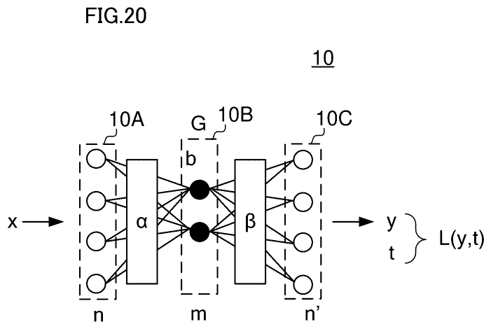

Here is given a description on one example of the machine learning model 40. For example, such a three-layer neural network 10 as shown in FIG. 20 is used as an AI model to be used for the machine learning model 40.

As shown in FIG. 20, the three-layer neural network 10 is an AI model including an input layer 10A, a hidden layer 10B, and an output layer 10C. In the three-layer neural network 10, generally, with respect to n-dimensional input data x∈R^{k×n} having a batch size of k, an n′-dimensional prediction result y∈R_{k×n′} can be obtained as y=G (x·α+b)β. In this connection, α∈R^{n×m} is a weight that connects the input layer 10A and the hidden layer 10B to each other, and BERm n′ is a weight that connects the hidden layer 10B and the output layer 10C to each other. Also, b∈R^{m} is a bias of the hidden layer 10B, and G is an activation function of the hidden layer 10B.

This embodiment employs an algorithm that allows the three-layer neural network 10 to be trained sequentially on an arbitrary batch-size basis. When ith training data {xᵢ ∈R^{k}ᵢ^{×n}, tᵢ∈R^{k}ᵢ^{×n′}} of the batch size kᵢ is obtained, it is necessary to determine βᵢ that minimizes an error represented by Expression (1) below.

$$‖ [ \begin{matrix}{H}_{0} \\ ⋮ \\ {H}_{i}\end{matrix} ] {β}_{i} - [ \begin{matrix}{t}_{0} \\ ⋮ \\ {t}_{i}\end{matrix} ] ‖ \qquad ( 1 )$$

It is noted that the ith hidden-layer matrix is Hᵢ=G(xᵢ·α+b). Also, t is training data corresponding to a prediction result y.

An optimized weight βᵢ is calculated by Expression (2) below.

$${P}_{i} = {P}_{i - 1} - {P}_{i - 1} {{H}_{i}^{T} ( I + {H}_{i} {P}_{i - 1} {H}_{i}^{T} )}^{- 1} {H}_{i} {P}_{i - 1} {β}_{i} = {β}_{i - 1} + {P}_{i} {H}_{i}^{T} ( {t}_{i} - {H}_{i} {β}_{i - 1} ) \qquad ( 2 )$$

Where, P₀ and β₀ are obtained by Expression (3) below.

$${P}_{0} = {( {H}_{0}^{T} {H}_{0} )}^{- 1} {β}_{0} = {P}_{0} {H}_{0}^{T} {t}_{0} \qquad ( 3 )$$

The algorithm of training is as follows:
(1) Initialize the values of the weight α and the bias b with random numbers.
(2) Calculate H₀ for x₀, and calculate P₀ and β₀.
(3) Every time the ith training data of batch size kᵢ is obtained, calculate Pᵢ and βᵢ. Here, β₀ need not be calculated according to the equation for its calculation in Expression (3); a value initialized with a random number can be taken as β₀.

In the third setting screen shown in FIG. 19, an AI parameter setting portion ST3 is displayed. Included in the AI parameter setting portion ST3 are an input-node-number setting portion ST31, a hidden-layer node number setting portion ST32, and an output-node-number setting portion ST33. In the input-node-number setting portion ST31, a node number (value of n mentioned above) of the input layer 10A is displayed. The node number of the input layer is calculated by multiplying a number of rows and a number of columns of one chunk in the input data. Enterable in the hidden-layer node number setting portion ST32 is a number of nodes (value of m mentioned above) of the hidden layer 10B. In the output-node-number setting portion ST33, a number of nodes (value of n′ mentioned above) of the output layer 10C. The number of nodes of the output layer is calculated by multiplying a number of rows and a number of columns in one chunk of training data. That is, one-chunk data corresponds to data having a batch size of 1.

The AI parameter setting portion ST3 also includes an activation-function setting portion ST34, a loss-function setting portion ST35, and a forgetting-rate setting portion ST36. In the activation-function setting portion ST34, a type of the activation function in the hidden layer 10B is selectable. For the activation function, Sigmoid, ReLU or the like is settable, as an example.

In the loss-function setting portion ST35, settable is a type of the loss function to be used for calculation of the anomaly score in the machine learning model 40. For the loss function, MAE or MSE may be set, as an example. Given MAE as the loss function, the loss function L is expressed as Expression (4) below:

$$L ( y , t ) = \frac{1}{{n}^{′}} \sum \vert y - t \vert \qquad ( 4 )$$

Also, given MSE as the loss function, the loss function L is expressed as Expression (5) below:

$$L ( y , t ) = \frac{1}{{n}^{′}} \sum {\vert y - t \vert}^{2} \qquad ( 5 )$$

In the forgetting-rate setting portion ST36, a value of the forgetting rate is enterable. The forgetting rate is a parameter representing a degree of forgettability for training results. Methods in which no training results are reflected may include, for example, using training results of the past, initializing training results, and the like. A forgetting rate of 1 represents no forgetting of past training results, while a forgetting rate of 0 represents forgetting all of training results.

In the third setting screen shown in FIG. 19, also displayed are a loading button BT7 for loading of the machine learning model 40 that has been saved (nontemporarily stored in the auxiliary storage device 100C), as well as a check box BX1. Saving of the machine learning model 40 will be described later.

When the loading button BT7 is pressed, a dialog box for designation of a machine learning model 40 to be loaded is displayed. When designation of the machine learning model 40 to be loaded is completed in the dialog box, the designated machine learning model 40 is loaded, followed by reflection of the loaded contents in the AI parameter setting portion ST3 as well as by automatic checking in the check box BX1.

By the loading button BT7 being pressed, it becomes practicable to use a machine learning model 40 (trained machine learning model 40) that has been non temporarily stored in the model storage unit 4 and subjected to computations of training. In addition, when the machine learning model 40 (trained machine learning model 40) after having been subjected to computations of training is used, it is appropriate to allow the user to make selection between, for example, a process of executing both computations of training and computations of prediction and a process of executing only computations of prediction without executing computations of training.

After settings of all the setting items have been completed by the above-described setting screens, and as a simulation start button BT8 is pressed, the model computing unit 5 executes a simulation according to contents set by the model setting unit 6. In this case, chunks of input data and training data, respectively, are sequentially fed to the machine learning model 40, followed by sequential updating of β by the above-described algorithm and execution of training. During the training, prediction associated with entry of input data into the machine learning model 40 is executed as well. Prediction results are calculated on the chunk basis of input data. Further, after the completion of training with input data entirely fed, prediction associated with entry of test input data into the machine learning model 40 is executed as well. Prediction results are calculated on the chunk basis of the test input data. These prediction results are compared with expected data.

After completion of the simulation, test results are displayed in a test result display area TA1 of the third setting screen as shown in FIG. 19.

In the test result display area TA1, anomaly score display areas TA11, TA12 are displayed. In the anomaly score display area TA11, test No. and test score are displayed in a table form in correspondence to each other. The test No. corresponds to the chunk number of expected data. That is, a maximum value of test No. is equal to a number of chunks. The test score, equivalent to anomaly score, is a value of the loss function based on prediction results on the chunk basis of expected data and the expected data. In the anomaly score display area TA12, an anomaly score is displayed in a graph form in which the test No. displayed in the anomaly score display area TA11 is plotted by the horizontal axis while the test score is plotted by the vertical axis.

In the test result display area TA1, also displayed are error display areas TA13, TA14. In the error display area TA13, row number (row No.), expected data (y_expected data), prediction data (y_actual), and error are displayed in a table form. The row No. is row number of expected data loaded in loading of a test-purpose file, where the expected data is given as expected data corresponding to a row number and the prediction data is a prediction result corresponding to the expected data. The error is an error between prediction data and expected data, being calculated by Expression (6) below:

$${error}_{i} = \frac{{y}_{{actual}_{i}} - {y}_{e x p e c t e {d}_{i}}}{{y}_{{expected}_{i}}} \qquad ( 6 )$$

In the example of FIG. 19, error_1 and error_2 are displayed as the error.

In the error display area TA14, anomaly score is displayed in a graph form in which a row number displayed in the error display area TA13 is plotted by the horizontal axis while an error is plotted by the vertical axis.

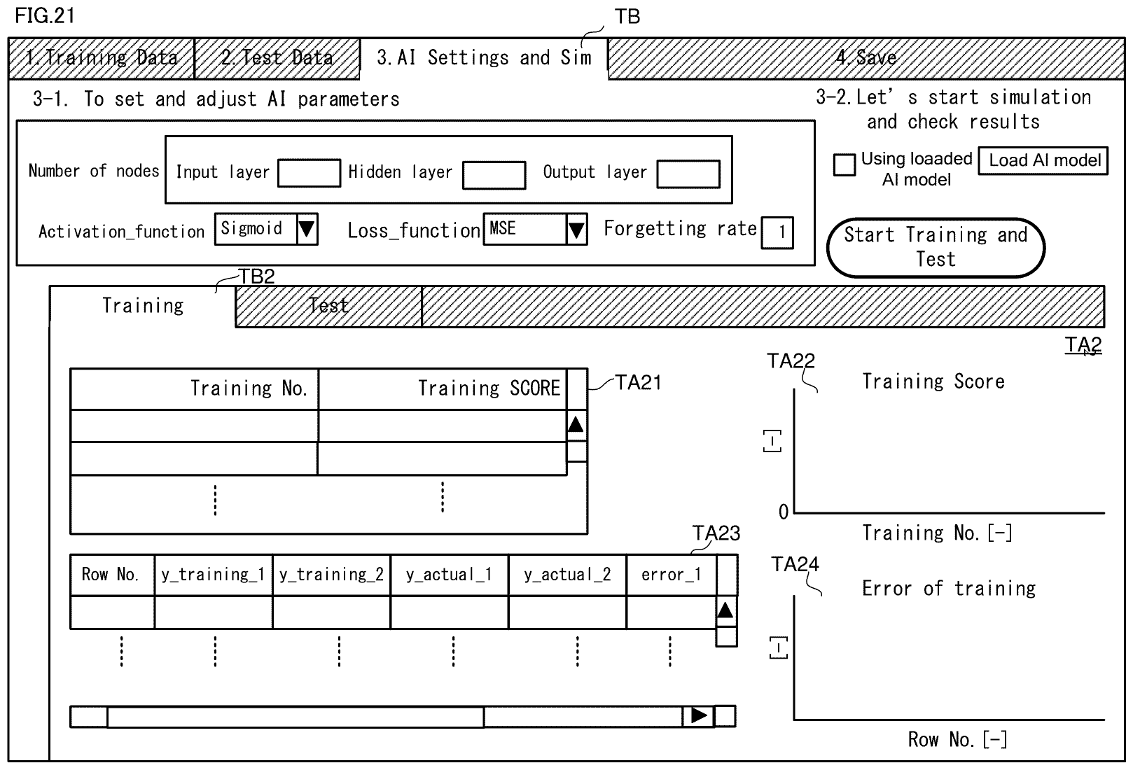

In the third setting screen, pressing a tab TB2 of “Training” causes a transition to a training result display area TA2 (FIG. 21). In the training result display area TA2, anomaly score (training score) display area TA21, TA22 are displayed. In the anomaly score display area TA21, training number (training No.) and training score (training SCORE) are displayed in a table form in correspondence to each other. The training No. corresponds to chunk number of training data. That is, a maximum value of training No. is equal to a number of chunks. The training score, equivalent to anomaly score, is a value of the loss function based on prediction results on the chunk basis of training data and the training data. In the anomaly score display area TA22, an anomaly score is displayed in a graph form in which the training No. displayed in the anomaly score display area TA21 is plotted by the horizontal axis while the training score is plotted by the vertical axis.

In the training result display area TA2, also displayed are error display areas TA23, TA24. In the error display area TA23, row number (row No.), training data (y_training), prediction data (y_actual), and errors are displayed in a table form. The row No. is row number of training data loaded in loading of a training-purpose file, where the training data is given as training data corresponding to a row number and the prediction data is a prediction result corresponding to the training data. The error is an error between prediction data and training data, being calculated by Expression (7) below:

$${error}_{i} = \frac{{y}_{{actual}_{i}} - {y}_{{training}_{i}}}{{y}_{{training}_{i}}} \qquad ( 7 )$$

In the example of FIG. 21, error_1 and error_2 are displayed as the error.

In the error display area TA24, anomaly score is displayed in a graph form in which row number displayed in the error display area TA23 is plotted by the horizontal axis while the error is plotted by the vertical axis.

### <<Save of Simulation Results>>

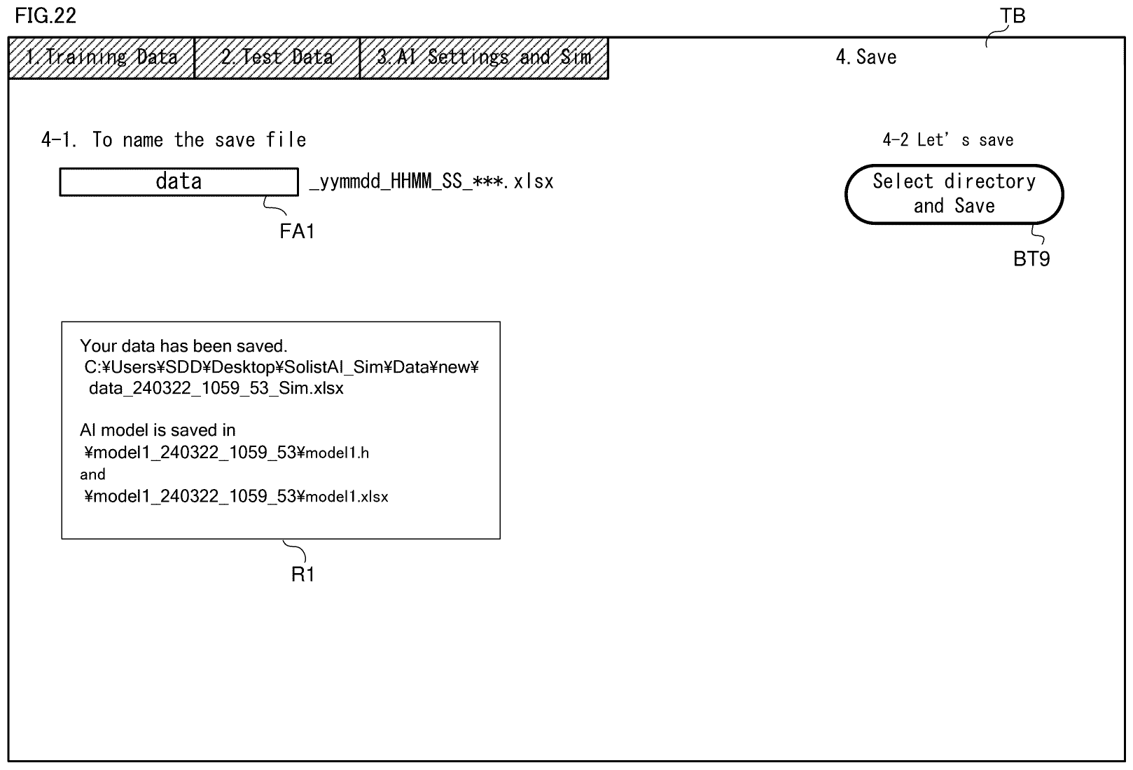

When a tab TB of “Save” is pressed, a save screen for saving of simulation results is displayed as shown in FIG. 22. In the save screen, a file name setting portion FA1 in which a file name for saving can be designated is displayed. In the file name setting portion FA1, first characters of the file name can be entered. In FIG. 22, character strings subsequent to the first characters are “_yymmdd_HHMM_SS_”, as an example. The file, having an extension of .xlsx, is saved as an Excel file. In the example of FIG. 22, “data” has been entered in the file name setting portion FA1. The save file shows a training result and a prediction result.

When a save button BT9 is pressed, a dialog box for selection of a folder serving as a save destination is displayed. With a save-destination folder selected in the dialog box, saving is started and, after completion of the saving, a save result RI is displayed.

In the save process described above, in addition to a file showing training results and prediction results, the machine learning model 40 (trained machine learning model 40) after execution of computations of training is non temporarily stored by the model storage unit 4. Accordingly, the model storage unit 4 non temporarily stores not only the machine learning model 40 before execution of the computations of training but also the machine learning model 40 (trained machine learning model 40) after execution of the computations of training. As a consequence of this, it becomes implementable to give over to other devices, the machine learning model 40 (trained machine learning model 40) after execution of the computations of training, and to perform sequential training and re-training with the machine learning model 40 (trained machine learning model 40) after execution of the computations of training, and the like.

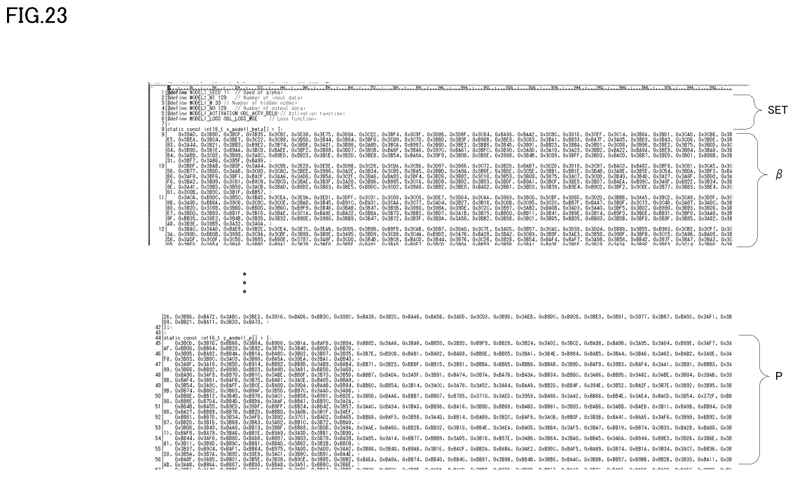

In the simulation apparatus 1, when an operation of, as an example, opening “model1_240322_1059_53¥model1.h” is performed, β and P that are internal parameters of the machine learning model 40 (trained machine learning model 40) after execution of the computations of training are displayed in a matrix form as shown in FIG. 23. In addition, the file identified by “model1_240322_1059_53¥model1.h” includes not only internal parameters of the machine learning model 40 (trained machine learning model 40) after execution of the computations of training but also setting contents SET of the machine learning model 40 (trained machine learning model 40) after execution of the computations of training. The setting contents SET include, for example, a node number of the input layer 10A, a node number of the hidden layer 10B, a node number of the output layer 10C, a type of the activation function of the hidden layer 10B, a type of the loss function, a random seed value of weight α, and the like.

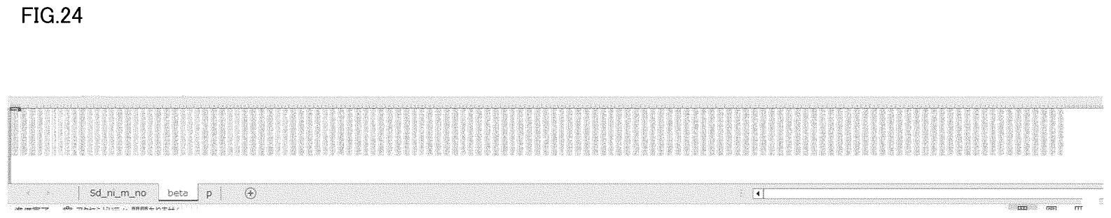

In the simulation apparatus 1, when an operation of, for example, opening “¥model1_240322_1059_53¥model1.xlsx” is performed and a sheet including data of β is selected, the data of β that is an internal parameter of the machine learning model 40 (trained machine learning model 40) after execution of the computations of training are displayed in a matrix form as shown in FIG. 24.

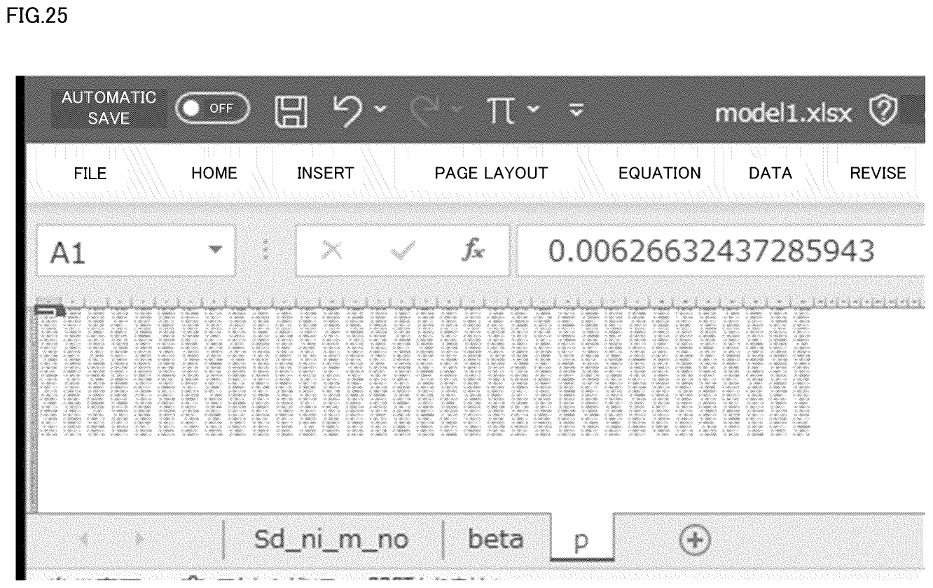

In the simulation apparatus 1, when an operation of, for example, opening “¥model1_240322_1059_53¥model1.xlsx” is performed and a sheet including data of β is selected, the data of P that is an internal parameter of the machine learning model 40 (trained machine learning model 40) after execution of the computations of training are displayed in a matrix form as shown in FIG. 25. The file identified by “¥model1_240322_1059_53¥model1.xlsx” includes not only internal parameters of the machine learning model 40 (trained machine learning model 40) after execution of the computations of training, but also a sheet including setting contents of the machine learning model 40 (trained machine learning model 40) after execution of the computations of training. The setting contents include, for example, a node number of the input layer 10A, a node number of the hidden layer 10B, a node number of the output layer 10C, a type of the activation function of the hidden layer 10B, a type of the loss function, a random seed value of weight α, a floating-point format, and the like.

As described above, this embodiment has practicalized a GUI that is suitable for verification of AI effect of supervised training, contributing to enhanced advantages for users.

### <Modifications>

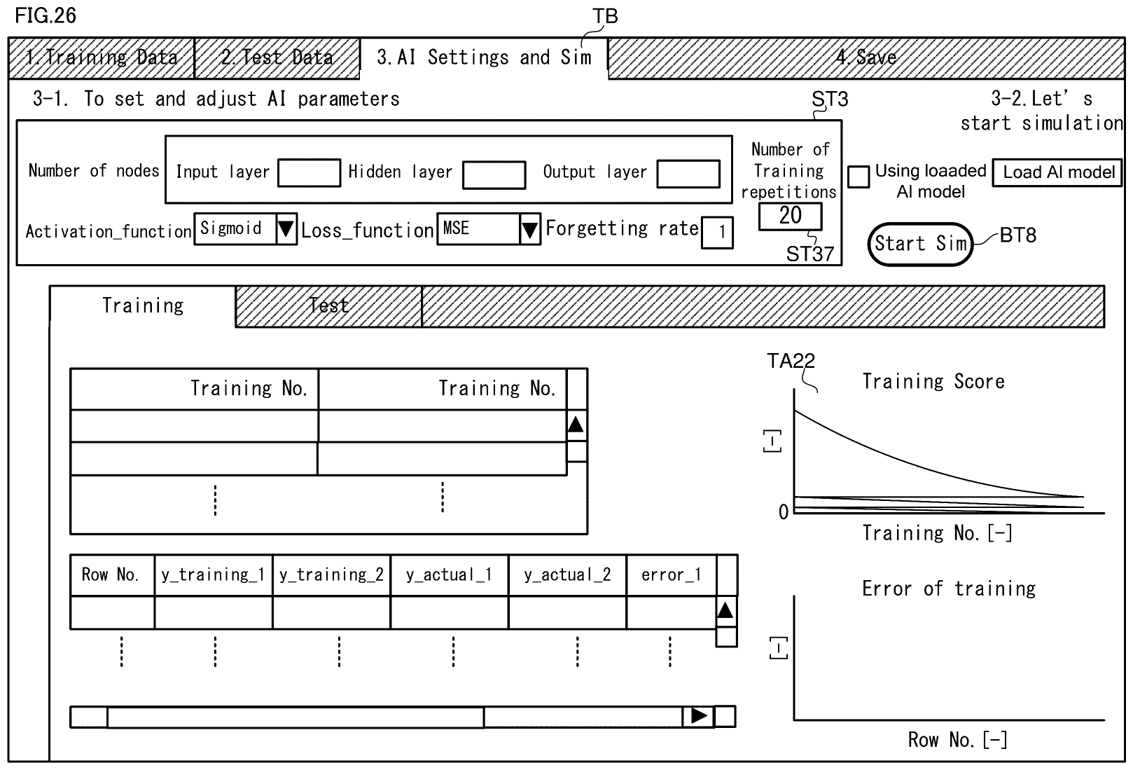

FIG. 26 is a view showing a third setting screen according to a modification. In this modification, in the AI parameter setting portion ST3 of the third setting screen in FIG. 19 according to the above-described embodiment, a number-of-training-repetitions setting portion ST37 is additionally provided.

In the number-of-training-repetitions setting portion ST37, a number of training repetitions is enterable. When the simulation start button BT8 is pressed with an input given in the number-of-training-repetitions setting portion ST37, training with use of all the chunks of input data is repeated to a number of times set in the number-of-training-repetitions setting portion ST37. That is, in a case where up to the last chunk is put into use, training is resumed with a return to the first chunk. As a result of this, as shown in FIG. 26, an aspect of training repetitions is displayed in the anomaly score display area TA22. According to such a modification, it becomes implementable to accomplish training such that the anomaly score (degree of training) approaches a plateau state without involving any increase in input data and training data.

### <Simulation of Full Charging Capacity>

As a case study of simulation with use of the simulation apparatus 1, a description is given on deterioration simulation of full charging capacity during a charging/discharging cycle test of batteries. For execution of the simulation, following assumptions are provided:
Assumption 1: Full charging capacity FC of a battery deteriorates (decreases) linearly to about 80% over 500 cycles;
Assumption 2: The larger the temperature T and the discharge current Ib, the earlier the deterioration;
Assumption 3: Therefore, it has been presumed that the full charging capacity FC is updated at every 10 cycles by Expression (8) below:

$$FC = F C \times ( 1 - 0.05 \times Rand ( ) - Ib \times 0 \text{.01} - T \times 0.00 \; 03 ) \qquad ( 8 )$$

where Rand( ) is a random function.

A full charging capacity FC1 for 100 cycles was determined by Expression (8) under conditions of unchanged temperature T and unchanged discharge current Ib, where the temperature T, the discharge current Ib, the cycle, and the full charging capacity FC1 are assumed as input data. In this case, a full charging capacity FC2 for 500 cycles after 100 cycles is determined by Expression (8), and this full charging capacity FC2 is taken as training data for one chunk.

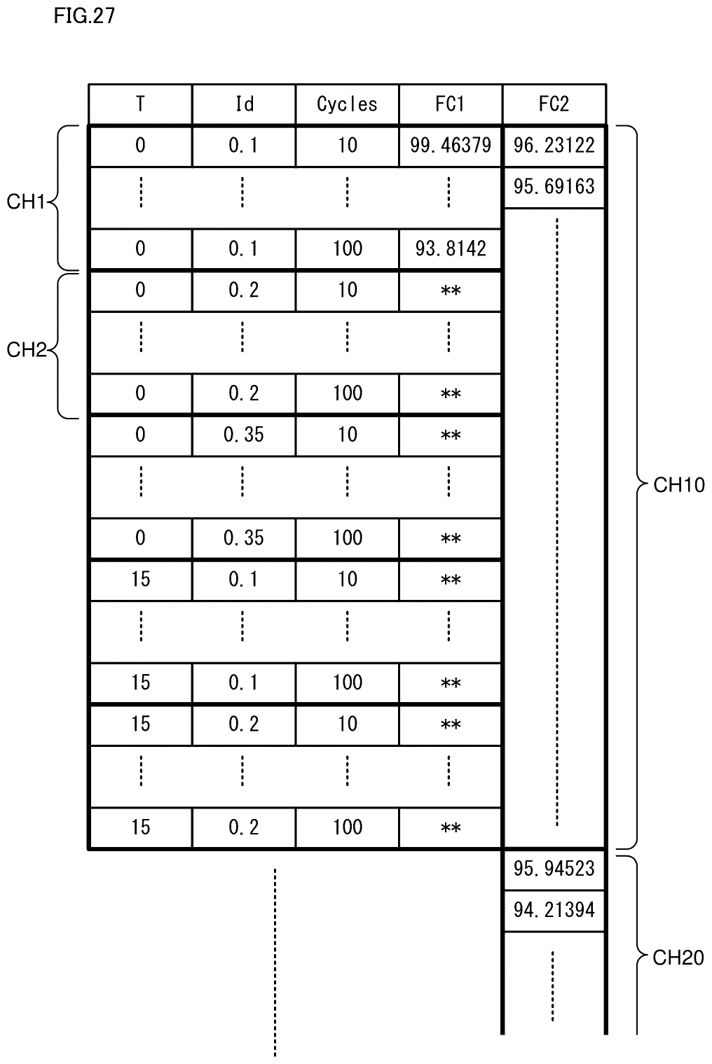

As an example, with the temperature T set to 0° C., 15° C., 25° C., 45° C. and 60° C., and with the discharge current Ib set to 0.1 A, 0.2 A and 0.35A, input data were prepared in totally 15 combinations of the temperature T and the discharge current Ib, and also training data corresponding to the input data were prepared. The training data prepared in this way are shown in FIG. 27. Input data CH1 and training data CH10 are in correspondence to each other, input data CH2 and training data CH20 are in correspondence to each other, and so on. One chunk of input data has a number of rows of 10 and a number of columns of 4, and one chunk of training data has a number of rows of 50 and a number of columns of 1. The number of chunks is 15.

Feeding such training data to the machine learning model 40 allows training to be executed. As test-purpose data, the full charging capacity FC1 for 100 cycles under conditions of unchanged temperature T and unchanged discharge current Ib as in input data is determined by the foregoing Expression (8), where the temperature T, the discharge current Ib, the cycle, and the full charging capacity FC1 are taken as test input data of one chunk. A full charging capacity FC2 for 500 cycles after 100 cycles is determined by the foregoing Expression (8), and the full charging capacity FC2 is taken as expected data of one chunk.

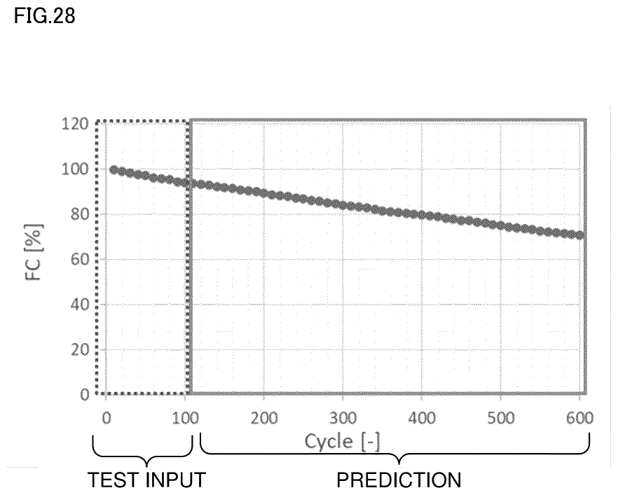

With use of such test-purpose data as described above, entering the test input data into the machine learning model 40 on the chunk basis, so that prediction of the full charging capacity can be executed and prediction results can be compared with expected data. Therefore, as shown in FIG. 28, the full charging capacity for future 500 cycles can be predicted from full charging capacity for 100 cycles, so that prediction accuracy can be verified.

### <Others>

In addition, various technical features disclosed herein may be carried out not only as in the above-described embodiment but also as changed or modified without departing from the gist of the technical creation of the disclosure. That is, the embodiment disclosed herein should be construed as not being limitative but being an exemplification at all points. The technical scope of the disclosure is defined not by the above description of the embodiment but by the appended claims, including all changes and modifications equivalent in sense and range to the claims.

For example, although chunks are set in a two-dimensional format with row number and column number in the above embodiment, it is also allowable to set the chunks in a three- or more-dimensional format.

### APPENDICES

As described hereinabove, a simulation apparatus (1) according to one aspect of the present disclosure comprises:
a model storage unit (4) in which a machine learning model (40) configured to execute training and prediction has been stored;
a model computing unit (5) configured to execute computing process by using the machine learning model;
an operation input portion (8);
a loading unit (3) configured to load training-purpose data (210) and test-purpose data (220); and
a model setting unit (6) configured to execute setting related to the machine learning model on a basis of input by the operation input portion,
wherein
on an assumption that a batch block of data in sequential feeding of data to the machine learning model is designated as a chunk,
the model setting unit is configured to, on a basis of the loaded training-purpose data, execute setting related to a first chunk as a chunk of input data as well as a second chunk as a chunk of training data, and further execute setting related to a third chunk as a chunk of test input data as well as a fourth chunk as a chunk of expected data,
the model computing unit is configured to execute computations of training with use of the machine learning model on a basis of the first chunk and the second chunk as well as computations of prediction with use of the machine learning model on a basis of results of the training and the third chunk, and to compute a comparison between results of the prediction and fourth chunk, and
the model storage unit is configured to non temporarily store not only the machine learning model before execution of the computations of training but also the machine learning model after execution of at least part of the computations of training (first configuration).

In the simulation apparatus of the first configuration, the model setting unit may be so configured that setting a column number as a first column, a number of rows, and a number of columns in the loaded training-purpose data enables setting of the first chunk and the second chunk (second configuration).

Also, in the simulation apparatus of the first or second configuration, the model setting unit may be so configured that a number of chunks in the first chunk is settable, and the first chunk and the second chunk are equal in number of chunks to each other (third configuration).

Also, in the simulation apparatus of any one of the first to third configurations, the model setting unit may be so configured that setting a column number as a first column, a number of rows, and a number of columns in the loaded test-purpose data enables setting of the third chunk and the fourth chunk (fourth configuration).

Also, in the simulation apparatus of the fourth configuration, the simulation apparatus may further include a first display control portion (7) which is so configured that when a number of rows and a number of columns in the first chunk are set, a number of rows and a number of columns of the third chunk corresponding to the number of rows and the number of columns of the first chunk, respectively, are automatically displayed, and when a number of rows and a number of columns of the second chunk are set, a number of rows and a number of columns of the fourth chunk corresponding to the number of rows and the number of columns of the second chunk, respectively, are automatically displayed (fifth configuration).

Also, in the simulation apparatus of any one of the first to fifth configurations, the model setting unit may be so configured that a number of chunks of the third chunk is settable, and the third chunk and the fourth chunk are equal in number of chunks to each other (sixth configuration).

Also, in the simulation apparatus of any one of the first to sixth configurations, the model setting unit may be so configured that items related to a neural network in the machine learning model are settable (seventh configuration).

Also, in the simulation apparatus of the seventh configuration, the items may include a forgetting rate which is a parameter representing a degree of forgettability for training results (eighth configuration).

Also, in the simulation apparatus of any one of the first to eighth configurations, the simulation apparatus may further include a second display control portion (7) configured to execute control for displaying values of a loss function based on prediction results during training by the machine learning model as well as on the training data on an every-turn basis of the second chunk (ninth configuration).

Also, in the simulation apparatus of any one of the first to ninth configurations, the simulation apparatus may further include a third display control portion (7) configured to execute control for displaying, as an error, a ratio of a difference between a prediction result during training by the machine learning model and the training data relative to the training data (tenth configuration).

Also, in the simulation apparatus of any one of the first to tenth configurations, the simulation apparatus may further include a fourth display control portion (7) configured to execute control for displaying values of a loss function based on prediction results of the machine learning model with use of the test input data as well as based on the expected data on an every-turn basis of the fourth chunk (eleventh configuration).

Also, in the simulation apparatus of any one of the first to eleventh configurations, the simulation apparatus may further include a fifth display control portion (7) configured to execute control for displaying, as an error, a ratio of a difference between a prediction result of the machine learning model with use of the test-purpose data and the expected data relative to the expected data (twelfth configuration).

Also, in the simulation apparatus of any one of the first to twelfth configurations, the model setting unit may be so configured that a number of repetitions to which training with use of all of the first chunks and the second chunks is repeatedly executed is settable (thirteenth configuration).

Also, in the simulation apparatus of any one of the first to thirteenth configurations, the simulation apparatus may further include a sixth display control portion (7) configured to execute control for displaying set leading chunks of the first chunks and the second chunks, respectively (fourteenth configuration).

Also, in the simulation apparatus of any one of the first to fourteenth configurations, the simulation apparatus may further include a seventh display control portion (7) configured to execute control for displaying the loaded training-purpose data (fifteenth configuration).

Also, in the simulation apparatus of any one of the first to fifteenth configurations, the simulation apparatus may further include an eighth display control portion (7) configured to execute control for displaying set leading chunks of the third chunks and the fourth chunks, respectively (sixteenth configuration).

Also, in the simulation apparatus of any one of the first to sixteenth configurations, the simulation apparatus may further include a ninth display control portion (7) configured to execute control for displaying the loaded test-purpose data (seventeenth configuration).

Also, in the simulation apparatus of any one of the first to seventeenth configurations, the training-purpose data and the test-purpose data may include temperature, discharge current, cycle number, and full charging capacity as each of the input data and the test input data, and
a full charging capacity for cycles subsequent to the cycle number may be included in the training-purpose data and the test-purpose data as the training data and the expected data, respectively (eighteenth configuration).

Also, in the simulation apparatus of any one of the first to eighteenth configurations, the model computing unit may be configured to be able to use the machine learning model which has been non temporarily stored by the model storage unit and which has been subjected to execution of at least part of the computations of training (nineteenth configuration).

Also, in the simulation apparatus of any one of the first to nineteenth configurations, the simulation apparatus may further include a tenth display control portion (7) configured to execute control for displaying, in a matrix form, part of contents of the machine learning model which has been non temporarily stored by the model storage unit and which has been subjected to execution of at least part of the computations of training (twentieth configuration).

Also, in the simulation apparatus of the twentieth configuration, the tenth display control portion may be configured to execute control for displaying, in a matrix form, information related to a weight that couples a hidden layer and an output layer to each other in the machine learning model which has been non temporarily stored by the model storage unit and which has been subjected to execution of at least part of the computations of training (twenty-first configuration).

Also, in the simulation apparatus of any one of the first to twenty-first configurations, the model computing unit may be configured to be able to execute only the computations of prediction without executing the computations of training in a case where the machine learning model which has been non temporarily stored by the model storage unit and which has been subjected to execution of at least part of the computations of training is used (twenty-second configuration).

Also, a program (P) according to one aspect of the present disclosure instructs a computer (100) to execute:
on an assumption that a batch block of data in sequential feeding of data to a machine learning model is designated as a chunk,
a first step of loading training-purpose data;
a second step of executing setting related to a first chunk as a chunk of input data and a second chunk as a chunk of training data on a basis of the loaded training-purpose data;
a third step of loading test-purpose data;
a fourth step of executing setting related to a third chunk as a chunk of input data and a fourth chunk as a chunk of expected data on a basis of the loaded test-purpose data;
a fifth step of executing computations of training with use of the machine learning model on a basis of the first chunk and the second chunk;
a sixth step of executing computations of prediction with use of the machine learning model on a basis of results of the training and the third chunk;
a seventh step of arithmetically comparing results of the prediction and the fourth chunk with each other; and
an eighth step of non temporarily storing, into a recording medium, the machine learning model after execution of at least part of the computations of training.

Also, a simulation method according to one aspect of the disclosure comprises:
on an assumption that a batch block of data in sequential feeding of data to a machine learning model is designated as a chunk,
a first step of loading training-purpose data;
a second step of executing setting related to a first chunk as a chunk of input data and a second chunk as a chunk of training data on a basis of the loaded training-purpose data;
a third step of loading test-purpose data;
a fourth step of executing setting related to a third chunk as a chunk of test input data and a fourth chunk as a chunk of expected data on a basis of the loaded test-purpose data;
a fifth step of executing computations of training with use of the machine learning model on a basis of the first chunk and the second chunk;
a sixth step of executing computations of prediction with use of the machine learning model on a basis of results of the training and the third chunk;
a seventh step of arithmetically comparing results of the prediction and the fourth chunk with each other; and
an eighth step of non temporarily storing, into a storage medium, the machine learning model after execution of at least part of the computations of training.

The present disclosure is utilizable for, for example, simulations of supervised training in various fields.

What is claimed is:

1. A simulation apparatus comprising:
a model storage unit in which a machine learning model configured to execute training and prediction has been stored;
a model computing unit configured to execute computing process by using the machine learning model;
an operation input portion;
a loading unit configured to load training-purpose data and test-purpose data; and
a model setting unit configured to execute setting related to the machine learning model on a basis of input by the operation input portion,
wherein
on an assumption that a batch block of data in sequential feeding of data to the machine learning model is designated as a chunk,
the model setting unit is configured to execute setting related to a first chunk as a chunk of input data and a second chunk as a chunk of training data on a basis of the loaded training-purpose data, and execute setting related to a third chunk as a chunk of test input data and a fourth chunk as a chunk of expected data on a basis of the loaded test-purpose data,
the model computing unit is configured to execute computations of training with use of the machine learning model on a basis of the first chunk and the second chunk, further execute computations of prediction with use of the machine learning model on a basis of results of the training and the third chunk, and arithmetically compare results of the prediction and the fourth chunk with each other, and
the model storage unit is configured to non temporarily store not only the machine learning model before execution of the computations of training but also the machine learning model after execution of at least part of the computations of training.

2. The simulation apparatus as claimed in claim 1, wherein
the model computing unit is configured to be able to use the machine learning model which has been non temporarily stored by the model storage unit and which has been subjected to execution of at least part of the computations of training.

3. The simulation apparatus as claimed in claim 1, further comprising:
a display control portion configured to execute control for displaying, in a matrix form, part of contents of the machine learning model which has been non temporarily stored by the model storage unit and which has been subjected to execution of at least part of the computations of training.

4. The simulation apparatus as claimed in claim 3, wherein
the display control portion is configured to execute control for displaying, in a matrix form, information related to a weight that couples a hidden layer and an output layer to each other in the machine learning model which has been non temporarily stored by the model storage unit and which has been subjected to execution of at least part of the computations of training.

5. The simulation apparatus as claimed in claim 1, wherein
the model computing unit is configured to be able to execute only the computations of prediction without executing the computations of training in a case where the machine learning model which has been non temporarily stored by the model storage unit and which has been subjected to execution of at least part of the computations of training is used.

6. A recording medium with a program recorded therein, wherein
the program instructs a computer to execute:
on an assumption that a batch block of data in sequential feeding of data to a machine learning model is designated as a chunk,
a first step of loading training-purpose data;
a second step of executing setting related to a first chunk as a chunk of input data and a second chunk as a chunk of training data on a basis of the loaded training-purpose data;
a third step of loading test-purpose data;
a fourth step of executing setting related to a third chunk as a chunk of test input data and a fourth chunk as a chunk of expected data on a basis of the loaded test-purpose data;
a fifth step of executing computations of training with use of the machine learning model on a basis of the first chunk and the second chunk;
a sixth step of executing computations of prediction with use of the machine learning model on a basis of results of the training and the third chunk;
a seventh step of arithmetically comparing results of the prediction and the fourth chunk with each other; and
an eighth step of non temporarily storing, in a storage medium, the machine learning model after execution of at least part of the computations of training.

7. A simulation method comprising:
on an assumption that a batch block of data in sequential feeding of data to a machine learning model is designated as a chunk,
a first step of loading training-purpose data;
a second step of executing setting related to a first chunk as a chunk of input data and a second chunk as a chunk of training data on a basis of the loaded training-purpose data;
a third step of loading test-purpose data;
a fourth step of executing setting related to a third chunk as a chunk of test input data and a fourth chunk as a chunk of expected data on a basis of the loaded test-purpose data;
a fifth step of executing computations of training with use of the machine learning model on a basis of the first chunk and the second chunk;
a sixth step of executing computations of prediction with use of the machine learning model on a basis of results of the training and the third chunk;
a seventh step of arithmetically comparing results of the prediction and the fourth chunk with each other; and
an eighth step of non temporarily storing, in a storage medium, the machine learning model after execution of at least part of the computations of training.
